(19) United States
(12) Patent Application Publication
(10) Pub. No.: US 2026/0101511 A1
(43) Pub. Date: Apr. 9, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventor: Kang Lib KIM, Suwon-si (KR)

(21) Appl. No.: 19/325,597

(22) Filed: Sep. 11, 2025

(30) Foreign Application Priority Data
Oct. 7, 2024 (KR) 10-2024-0136087

(51) Int. Cl. H10B 43/27; H01L 23/00; H01L 25/18; H10B 41/10; H10B 41/27; H10B 41/35; H10B 41/41; H10B 43/10; H10B 43/35; H10B 43/40; H10B 80/00; H10D 80/30

(52) U.S. Cl. CPC H10B 43/27; H10B 41/10; H10B 41/27; H10B 41/35; H10B 41/41; H10B 43/10; H10B 43/35; H10B 43/40; H10B 80/00; H10D 80/30; H10W 90/00; H10W 90/20; H10W 90/24; H10W 90/732; H10W 90/734; H10W 90/752; H10W 90/754; H10W 90/792

(57) ABSTRACT

A semiconductor device includes a substrate that includes a cell array region and a connection region, first gate stack structures and second gate stack structures, channel structures that extend into a first set of the first gate stack structures and a first set of the second gate stack structures that are on the cell array region, first gate contact portions that extend into a second set of the first gate stack structures that are on the connection region, second gate contact portions that extend into a second set of the second gate stack structures that are on the connection region, a first separation pattern that is between the first set of first gate stack structures and the first set of second gate stack structures, and a second separation pattern that is between the second set of first gate stack structures and the second set of second gate stack structures.

### CROSS-REFERENCE TO RELATED APPLICATION

This application claims priority to and the benefit of Korean Patent Application No. 10-2024-0136087, filed in the Korean Intellectual Property Office on Oct. 7, 2024, the entire contents of which are incorporated herein by reference.

### TECHNICAL FIELD

The present disclosure relates to a semiconductor device and an electronic system including the same.

### BACKGROUND

Semiconductor memory devices may be broadly divided into volatile memory devices and nonvolatile memory devices. The volatile memory devices are memory devices in which stored data disappears when power is cut off, and examples include dynamic random access memory (DRAM) and a static random access memory (SRAM). The nonvolatile memory devices are memory devices in which stored data is not lost even when power supply is cut off, and examples include a programmable ROM (PROM), an erasable PROM (EPROM), an electrically EPROM (EEPROM), and a flash memory device. Furthermore, in line with the recent trend toward higher performance and lower power consumption of semiconductor memory devices, next-generation semiconductor memory devices with nonvolatility, such as a magnetic random access memory (MRAM), a phase-change random access memory (PRAM), and a ferroelectric random access memory (FeRAM), are being developed. As high integration and high performance of semiconductor devices are demanded, various studies are being conducted using semiconductor devices with different characteristics.

### SUMMARY

Embodiments attempt to provide a semiconductor device and an electronic system including the same, capable of improving efficiency of a process and reducing an overall size thereof.

Some embodiments of the present disclosure provide a semiconductor device including: a substrate that includes a cell array region and a connection region, first gate stack structures and second gate stack structures that are spaced apart from each other in a first direction and are on the cell array region and the connection region, where each of the first gate stack structures and the second gate stack structures includes interlayer insulating layers and gate electrodes that are alternately stacked, channel structures that extend into a first set of the first gate stack structures and a first set of the second gate stack structures that are on the cell array region, first gate contact portions that extend into a second set of the first gate stack structures that are on the connection region, second gate contact portions that extend into a second set of the second gate stack structures that are on the connection region, a first separation pattern that is between the first set of first gate stack structures and the first set of second gate stack structures and extends in a second direction intersecting the first direction, and a second separation pattern that is between the second set of first gate stack structures and the second set of second gate stack structures, where a first end of the second separation pattern contacts the first separation pattern, and where the second separation pattern extends diagonally between the first direction and the second direction.

Some embodiments of the present disclosure provide a semiconductor device including: a substrate that includes a cell array region and a connection region, first gate stack structures and second gate stack structures that are spaced apart from each other in a first direction and are on the cell array region and the connection region, where each of the first gate stack structures and the second gate stack structures includes interlayer insulating layers and gate electrodes that are alternately stacked, channel structures that extend into a first set of the first gate stack structures and a first set of the second gate stack structures in the cell array region, first gate contact portions that extend into a second set of the first gate stack structures that are on the connection region, second gate contact portions that extend into a second set of the second gate stack structures that are on the connection region, a first separation pattern that is between the first set of first gate stack structures and the first set of second gate stack structures and extends in a second direction intersecting the first direction, and second separation pattern that is between the second set of first gate stack structures and the second set of second gate stack structures and includes a first end that contacts the second separation pattern, where a width in the first direction of a portion of the second separation pattern that at least partially overlaps the gate electrode in the first direction is different from a width of a region that at least partially overlaps the interlayer insulating layer in the first direction.

Some embodiments of the present disclosure provide an electronic system including: a main substrate, a semiconductor device on the main substrate, and a controller electrically connected to the semiconductor device on the main substrate, where the semiconductor device includes: a substrate that includes a cell array region and a connection region, first gate stack structures and second gate stack structures that are spaced apart from each other in a first direction and are on the cell array region and the connection region, where each of the first gate stack structures and the second gate stack structures includes interlayer insulating layers and gate electrodes that are alternately stacked, channel structures that extend into a first set of the first gate stack structures and a first set of the second gate stack structures that are on the cell array region, first gate contact portions that extend into a second set of the first gate stack structures that are on the connection region, second gate contact portions that extend into a second set of the second gate stack structures that are on the connection region, a first separation pattern that is between the first set of first gate stack structures and the first set of second gate stack structures and extends in a second direction intersecting the first direction, and a second separation pattern that is between the second set of first gate stack structures and the second set of second gate stack structures, where a first end of the second separation pattern contacts the first separation pattern, and where the second separation pattern extends diagonally between the first direction and the second direction.

A semiconductor device according to some embodiments may include separation patterns separating between two blocks, where connection regions may be separated by the separation patterns formed by support structures.

According to some embodiments, gate contact portions may be efficiently arranged within a connection region, thereby reducing a width of an entire connection region and reducing a size of a semiconductor device according to some embodiments.

### BRIEF DESCRIPTION OF THE DRAWINGS

FIG. 1 illustrates a plan view showing a semiconductor device according to some embodiments.

FIG. 2 illustrates an enlarged plan view of a region A in FIG. 1.

FIG. 3 illustrates a partial cross-sectional view of a semiconductor device taken along lines I1-I1′ of FIG. 1 and I2-I2′ of FIG. 2.

FIG. 4 illustrate an enlarged cross-sectional view showing an example of a channel structure included in the semiconductor device illustrated in FIG. 3.

FIG. 5 illustrates a cross-sectional view showing a connection region included in the semiconductor device illustrated in FIG. 3.

FIG. 6 illustrates a cross-sectional view of a portion B in FIG. 5.

FIG. 7 illustrates a cross-sectional view of a semiconductor device taken along line I3-I3′ in FIG. 1.

FIG. 8 illustrates a cross-sectional view of a semiconductor device taken along line I4-I4′ in FIG. 1.

FIG. 9 illustrates a plan view showing a semiconductor device according to some embodiments.

FIG. 10 illustrates a plan view showing a semiconductor device according to some embodiments.

FIG. 11 illustrates a plan view showing a semiconductor device according to some embodiments.

FIG. 12 to FIG. 33 illustrate process cross-sectional views for describing a manufacturing method for a semiconductor package according to some embodiments.

FIG. 34 illustrates a partial cross-sectional view schematically showing a semiconductor device according to.

FIG. 35 schematically illustrates an electronic system including a semiconductor device according to some embodiments.

FIG. 36 illustrates a schematic perspective view showing an electronic system including a semiconductor device according to some embodiments.

FIG. 37 illustrates a schematic cross-sectional view of a semiconductor package according to some embodiments.

FIG. 38 illustrates a schematic cross-sectional view of a semiconductor package according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the scope of the present disclosure.

To clearly describe the present disclosure, parts that are irrelevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

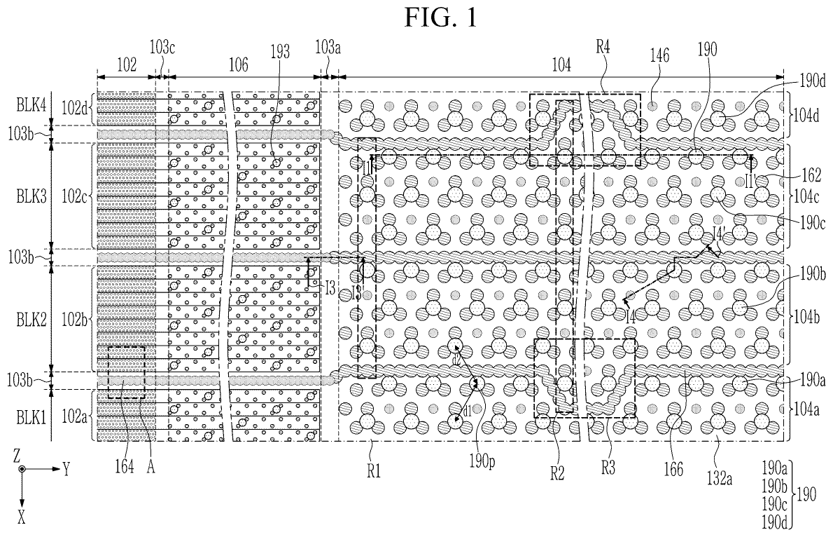

FIG. 1 to FIG. 4 illustrate top plan views and cross-sectional views for describing a manufacturing method for a semiconductor package according to some embodiments.

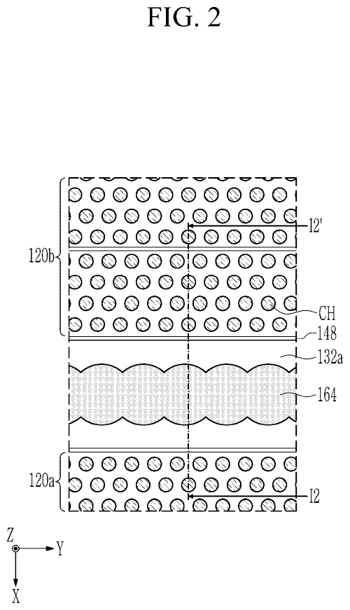

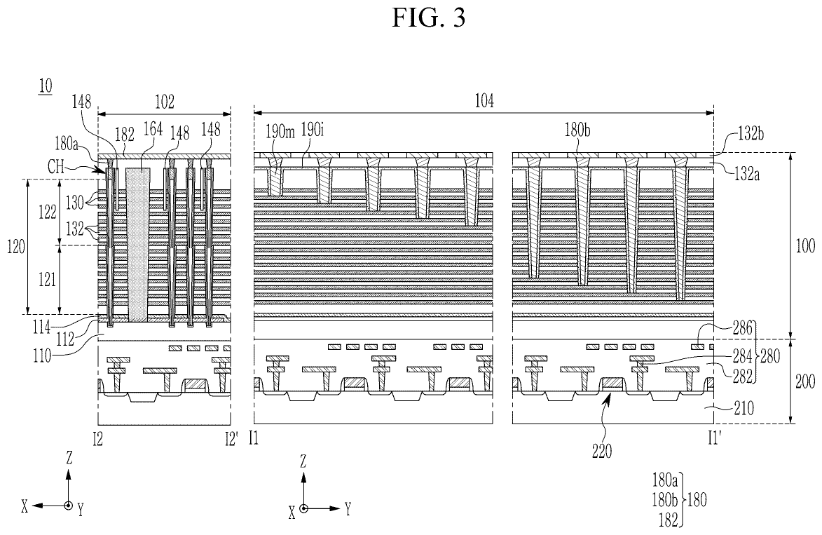

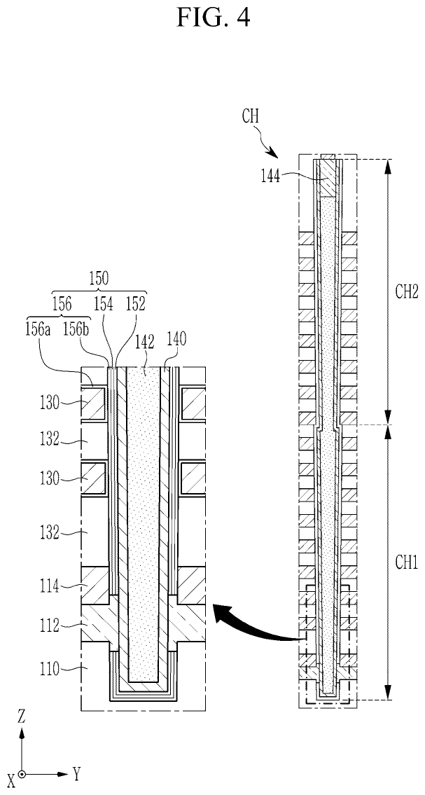

FIG. 1 illustrates a top plan view showing a semiconductor device according to some embodiments, FIG. 2 illustrates an enlarged plan view of a region A in FIG. 1, FIG. 3 illustrates a partial cross-sectional view of a semiconductor device taken along lines I1-I1′ and I2-I2′ in FIG. 1 and FIG. 2, and FIG. 4 illustrate an enlarged cross-sectional view showing an example of a channel structure included in the semiconductor device illustrated in FIG. 3.

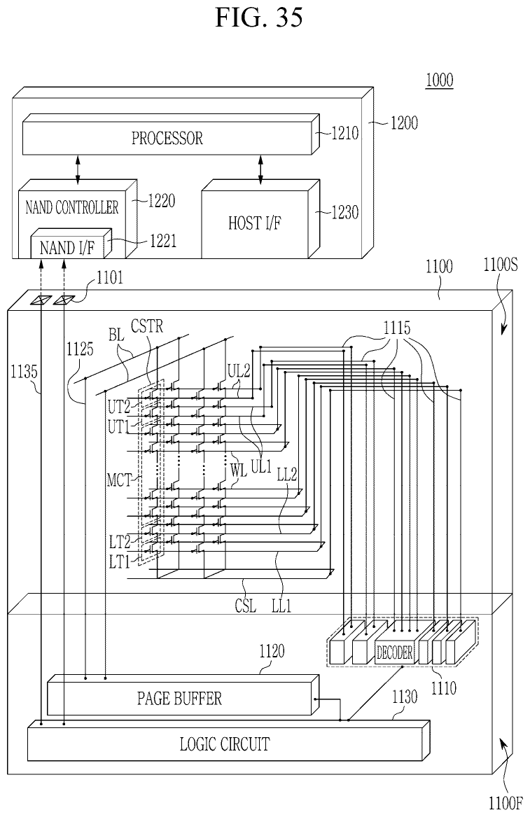

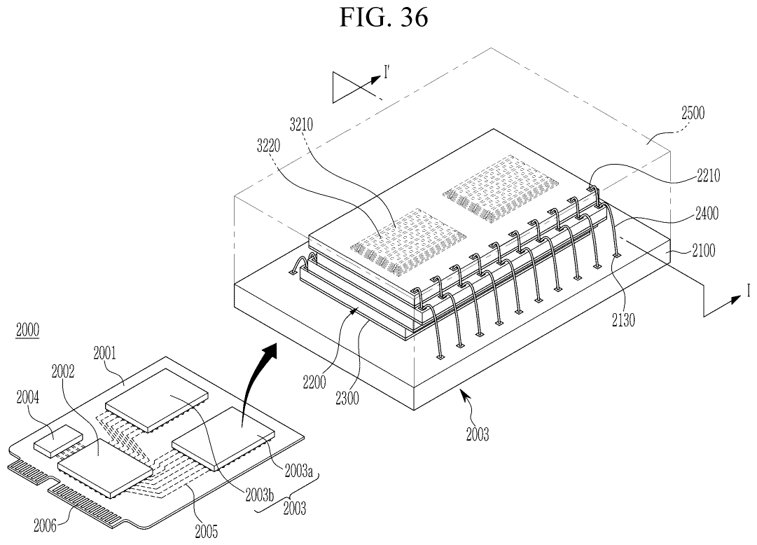

Referring to FIG. 1 to FIG. 4, a semiconductor device 10 according to some embodiments may include a cell region 100 having a memory cell structure including a plurality of memory cells, and a circuit region 200 having a peripheral circuit structure configured to control an operation of the memory cell structure. For example, the circuit region 200 and the cell region 100 may respectively be portions corresponding to a first structure 1100F and a second structure 1100S of a semiconductor device 1100 included in an electronic system 1000 illustrated in FIG. 35. In some embodiments, the circuit region 200 and the cell region 100 may be portions including a first structure 3100 and a second structure 3200 of a semiconductor chip 2200 illustrated in FIG. 36, respectively.

The circuit region 200 may include a peripheral circuit structure formed on a first substrate 210, and the cell region 100 may include a gate stack structure 120 and a channel structure CH formed on the second substrate 110 as a memory cell structure. The circuit region 200 may include a first wire portion 280, and the cell region 100 may include a second wiring portion 180 electrically connected to the memory cell structure.

In some embodiments, the cell region 100 may be positioned on the circuit region 200. Accordingly, an area corresponding to the circuit region 200 may not need to be secured separately from the cell region 100, so an area of the semiconductor device 10 may be reduced. However, the embodiments are not limited thereto, and the circuit region 200 may be positioned next to the cell region 100. Numerous other variations are possible.

The circuit region 200 may include the first substrate 210, a circuit element 220 and the first wire portion 280 positioned on a first surface of the first substrate 210.

The first substrate 210 may be a semiconductor substrate including a semiconductor material. For example, the first substrate 210 may be a semiconductor substrate made of a semiconductor material or may be a semiconductor substrate on which a semiconductor layer is formed on a base substrate. For example, the first substrate 210 may be formed of single crystal or polycrystalline silicon, epitaxial silicon, germanium, silicon-germanium, silicon-on-insulator, or germanium-on-insulator.

The circuit element 220 formed on the first substrate 210 may include various circuit elements that control the operation of the memory cell structure provided in the cell region 100. For example, the circuit element 220 may configure peripheral circuit structures such as a decoder circuit (reference numeral 1110 in FIG. 35), a page buffer (reference numeral 1120 in FIG. 35), and a logic circuit (reference numeral 1130 in FIG. 35).

The circuit element 220 may include, e.g., a plurality of transistors, but the embodiments are not limited thereto. The circuit element 220 may include not only active elements such as transistors, but also passive elements such as capacitors, resistors, and inductors.

The first wire portion 280 positioned on the first substrate 210 may be electrically connected to the circuit element 220. In some embodiments, the first wire portion 280 may include a plurality of wiring layers 286 spaced apart with an interlayer insulating layer 282 provided therebetween and connected to form a desired path by a contact via 284. The wiring layer 286 or the contact via 284 may include various conductive materials, and the interlayer insulating layer 282 may include various insulating materials. For example, the interlayer insulating layer 282 may include at least one of a silicon oxide, a silicon nitride, or a silicon oxynitride.

In some embodiments, the cell region 100 may include a plurality of blocks BLK. The block BLK may be a unit in which data is stored and managed in a semiconductor device according to some embodiments. For example, each of the blocks BLK may include a plurality of memory cells, and data may be stored in the memory cells included in each of the blocks BLK. For example, data stored in the semiconductor device may be erased in units of block BLK.

The blocks BLK may be positioned separately from each other within the semiconductor device. Referring to FIGS. 1 and 3, the blocks BLK may be arranged spaced apart in a first direction X. Although four blocks BLK1, BLK2, BLK3, and BLK4 are illustrated in FIG. 1, a number of blocks BLK included in one semiconductor device is not limited. In some embodiments, the blocks BLK1 to BLK4 may be arranged spaced apart from each other along the first direction X. However, positions of the blocks BLK are not limited thereto, and may be arranged in various forms on the second substrate 110. In some embodiments, a plurality of blocks BLK may be partitioned on the second substrate 110 by separation patterns 164 and 166 to be described later.

The cell region 100 may include a cell array region 102 and a connection region 104. In some embodiments, each of the blocks BLK included in the cell region 100 may include the cell array region 102 and the connection region 104. Specifically, referring to FIG. 1, the first block BLK1 may include a first cell array region 102a and a first connection region 104a, the second block BLK2 may include a second cell array region 102b and a second connection region 104b, the third block BLK3 may include a third cell array region 102c and a third connection region 104c, and the fourth block BLK4 may include a fourth cell array region 102d and a fourth connection region 104d. For example, within each of the blocks BLK, the cell array region 102 and the connection region 104 may be spaced apart from each other in a second direction Y.

In some embodiments, the second substrate 110 may include a semiconductor layer including a semiconductor material. For example, the second substrate 110 may be a semiconductor substrate made of a semiconductor material or may be a substrate on which a semiconductor layer is disposed on a base substrate. For example, the second substrate 110 may include, e.g., silicon, germanium, silicon-germanium, silicon-on-insulator (SOI), or germanium-on-insulator (GOI). Herein, a p-type or n-type impurity may be doped into a semiconductor layer included in the second substrate 110. For example, the p-type impurity may include boron (B), gallium (Ga), etc., and the n-type impurity may include phosphorus (P), arsenic (As), etc. However, the embodiments are not limited to the material of the second substrate 110, the conductive type of the impurity doped in the semiconductor layer, or the material described herein.

In the cell array region 102, the gate stack structure 120 includes interlayer insulating layers 132 and gate electrodes 130 alternately stacked on a first surface (e.g., an upper surface) of the second substrate 110, and the channel structure CH extends in a direction (Z-axis direction in the drawing) through the gate stack structure 120 and intersects (e.g., perpendicular) with the second substrate 110 may be formed. In some embodiments, the gate stack structure 120 may extend to the connection region 104. A structure for connecting the gate stack structure 120 and/or the channel structure CH formed in the cell array region 102 to the circuit region 200 or an external circuit may be positioned in the cell array region 102 and/or the connection region 104.

In some embodiments, horizontal conductive layers 112 and 114 may be included between the second substrate 110 and the gate stack structure 120 in the cell array region 102 to electrically connect (e.g., directly connect) the channel structure CH and the second substrate 110. The horizontal conductive layers 112 and 114 may include a first horizontal conductive layer 112 and/or a second horizontal conductive layer 114 sequentially positioned on the second substrate 110. The first horizontal conductive layer 112 may function as a portion of a common source line of the semiconductor device 10. For example, the first horizontal conductive layer 112 and the second substrate 110 may function as the common source line.

The first and second horizontal conductive layers 112 and 114 may include a semiconductor material (e.g., polycrystalline silicon). For example, the first horizontal conductive layer 112 may include a polycrystalline silicon layer containing impurities. The embodiments are not limited thereto, and the second horizontal conductive layer 114 may be formed of a different material (e.g., an insulating material) from that of the first horizontal conductive layer 112, or the second horizontal conductive layer 114 may be omitted.

The gate stack structure 120 in which the interlayer insulating layers 132 and the gate electrodes 130 are alternately stacked may be positioned on the second substrate 110 (e.g., on the first and second horizontal conductive layers 112 and 114 positioned on the second substrate 110).

The gate electrode 130 may include various conductive materials. For example, the gate electrode 130 may include a metal material such as tungsten (W), copper (Cu), aluminum (Al), polycrystalline silicon, a metal nitride (e.g., titanium nitride (TiN), tantalum nitride (TaN), etc.), or a combination thereof. As shown in the enlarged view of FIG. 4, a part of the blocking layer 156 made of an insulating material (e.g., a first blocking layer 156a) may be positioned on the outside of the gate electrode 130. The interlayer insulating layer 132 may include various insulating materials. For example, the interlayer insulating layer 132 may include a silicon oxide, a silicon nitride, a silicon oxynitride, a low dielectric constant material having lower permittivity than that of the silicon oxide, or a combination thereof.

In some embodiments, the channel structure CH may be formed to extend in a direction (Z-axis direction in the drawing) that intersects (e.g., perpendicular to) the second substrate 110 through the gate stack structure 120.

The channel structure CH may include a channel layer 140 and a gate dielectric layer 150 disposed on the channel layer 140 between the gate electrode 130 and the channel layer 140. The channel structure CH may further include a core insulating layer 142 positioned inside the channel layer 140, but as another example, the core insulating layer 142 may not be provided. The channel structure CH may further include a channel pad 144 disposed on the channel layer 140 and/or the gate dielectric layer 150. The gate dielectric layer 150 positioned between the gate electrode 130 and the channel layer 140 may include a tunneling layer 152, a charge storage layer 154, and a blocking layer 156 sequentially disposed on the channel layer 140.

Each channel structure CH forms one memory cell string, and a plurality of channel structures CH may be spaced apart from each other while forming rows and columns in a plan view. For example, the channel structures CH may be arranged in various forms such as a lattice form or a zigzag form in a plan view. The channel structures CH may each have a columnar shape. For example, when the channel structure CH is viewed in a cross-sectional view, it may have an inclined side surface such that its width narrows as it approaches the second substrate 110 according to an aspect ratio. However, the embodiments are not limited thereto, and the arrangement, structure, and form of the channel structure CH may be variously modified.

The first channel layer 140 may include a semiconductor material, e.g., polycrystalline silicon. The core insulating layer 142 may include various insulating materials. For example, the core insulating layer 142 may include a silicon oxide, a silicon nitride, a silicon oxynitride, or a combination thereof.

The tunneling layer 152 may include an insulating material capable of tunneling charges (e.g., a silicon oxide, a silicon nitride, etc.). The charge storage layer 154 is used as a data storage region, and the charge storage layer 154 may include polycrystalline silicon, a silicon nitride, or the like. The blocking layer 156 may include an insulating material capable of preventing an undesirable flow of charges into the gate electrode 130. For example, the blocking layer 156 may include a silicon oxide, a silicon nitride, a silicon oxynitride, a high-k material having a higher permittivity than silicon oxide, or a combination thereof. In some embodiments, the blocking layer 156 may include a first blocking layer 156aincluding a portion extending horizontally along the gate electrode 130, and a second blocking layer 156b extending vertically between the first blocking layer 156a and the charge storage layer 154.

However, the materials, stacked structures, etc. of the channel layer 140, the core insulating layer 142, and the gate dielectric layer 150 may be modified in various ways, and the embodiments are not limited thereto.

The channel pad 144 may be positioned to cover or at least partially overlap an upper surface of the core insulating layer 142 and to be electrically connected to the channel layer 140. The channel pad 144 may include a conductive material, e.g., polycrystalline silicon doped with impurities, but the embodiments are not limited thereto.

In some embodiments, channel structures CH may be positioned in each of the blocks BLK. The channel structures CH may be arranged at regular intervals within the cell array region 102 of each of the blocks BLK, but the embodiments are not limited thereto. For example, in at least some regions within the cell array region 102, the intervals between channel structures CH may not be constant. Referring to FIGS. 1 and 2, the channel structures CH may be arranged spaced apart from each other along the first direction X and the second direction Y. The channel structures CH may be arranged in a row along the first direction X and in a zigzag manner along the second direction Y. However, the embodiments are not limited thereto, and the channel structures CH within the cell array region 102 may be arranged in various shapes. For example, the channel structures CH may be arranged in a matrix shape or in a hexagonal shape within the cell array region 102. A number of channel structures CH included in each of the blocks BLK may be the same. However, the embodiments are not limited thereto, and at least some of the blocks BLK may have a different number of channel structures CH than a number of channel structures CH included in other blocks BLK.

Referring to FIGS. 1 and 2, upper separation regions 148, which will be described later, may be positioned between at least some of the channel structures CH positioned within the block BLK.

In some embodiments, the cell region 100 may include a plurality of gate stack portions 121 and 122 in which gate stack structures 120 are sequentially stacked. Then, a number of stacked gate electrodes 130 may be increased, so a number of memory cells may be increased with a stable structure. In FIG. 3, the gate stack structure 120 is illustrated as including two gate stack portions 121 and 122, but the gate stack structure 120 may include one or three or more gate stack structures.

As described above, when a plurality of gate stack portions 121 and 122 are provided, a plurality of channel portions CH1 and CH2 each having a form in which the channel structure CH extends through or into each of the gate stack portions 121 and 122 and are connected to each other may be provided. Each of the channel portions CH1 and CH2 has an inclined side surface such that a width becomes narrower as it approaches the second substrate 110 according to the aspect ratio when viewed in cross-section, and a bent portion due to a width difference may be provided at a boundary of the channel portions CH1 and CH2. As another example, the channel portions CH1 and CH2 may have inclined side surfaces that are continuously connected without any bent portions. In FIG. 2, it is illustrated that the gate dielectric layer 150, the channel layer 140, and the core insulating layer 142 of the channel portions CH1 and CH2 extend from each other to have an integral structure. As another example, the gate dielectric layer 150, the channel layer 140, and the core insulating layer 142 of the channel portions CH1 and CH2 may be formed separately from each other and electrically connected to each other, or a separate channel pad may be additionally provided at a boundary of the channel portions CH1 and CH2. In this way, the embodiments are not limited to the form of the channel portions CH1 and CH2.

In some embodiments, the gate stack structure 120 may be divided or separated into multiple portions in a plan view by separation patterns 164 and 166 to be described later. Accordingly, each of the blocks BLK may include at least one gate stack structure 120. For example, as illustrated in FIG. 2, the first block BLK1 may include the first gate stack structure 120a, and the second block BLK2 may include the second gate stacking structure 120b. Although not explicitly shown in FIGS. 1 to 4, the third block BLK3 may include a third gate stack structure, and the fourth block BLK4 may include a fourth gate stack structure. The gate stack structure 120 may be spaced apart from each other in the first direction X. The separation patterns 164 and 166 may be positioned between each of the gate stack structures 120. Referring to FIG. 1, a first separation pattern 164 may be positioned between the gate stack structures 120 positioned in the cell array region 102, and a second separation pattern 166 may be positioned between the gate stack structures 120 positioned in the connection region 104. The first separation pattern 164 and the second separation pattern 166 may have different structures, and may be formed in different processes. The first separation pattern 164 and the second separation pattern 166 may include different materials. The first separation pattern 164 and the second separation pattern 166 may be connected, and a boundary between the first separation pattern 164 and the second separation pattern 166 may be provided or recognized.

The connection region 104 and the second wire portion 180 may be provided to connect the gate stack structure 120 and the channel structure CH provided in the cell array region 102 to the circuit region 200 or an external circuit. The connection region 104 may be positioned around the cell array region 102. For example, the connection region 104 may be positioned at a first side of the cell array region 102. Referring to FIG. 1, the connection region 104 may be spaced apart from the cell array region 102 in the second direction Y, but the embodiments are not limited thereto.

A portion of the second wiring portion 180 may be positioned in the connection region 104, and another portion may be positioned in the cell array region 102. The second wire portion 180 may include all members or elements electrically connecting the gate electrode 130, the channel structure CH, the horizontal conductive layers 112 and 114, and/or the second substrate 110 to the circuit region 200 or an external circuit. For example, the second wiring portion 180 may include a bitline 182, a bitline contact via 180a, a gate contact via 180b, an insulating layer 132b, and a connection wire (not shown).

The bitline 182 may extend in a cross direction (X-axis direction in the drawing) that intersects an extension direction (Y-axis direction in the drawing) of the gate electrode 130. The bitline 182 may be electrically connected to the channel structure CH, for example, the channel pad 144, through the bitline contact via 180a extending through the interlayer insulating layer 132.

In some embodiments, at least a portion of the gate stack structure 120 may be positioned in the connection region 104. More specifically, the gate stack structure 120 may be positioned together in the cell array region 102 and the connection region 104. For example, extension lengths of the gate electrodes 130 in the connection region (104) may be substantially the same. Herein, being substantially the same includes cases where there is a difference within a process error (e.g., within 10%). In the connection region 104, a plurality of gate contact portions 190 may extend through or into the gate stack structure 120, to be electrically connected to a plurality of gate electrodes 130, respectively. Each of the gate contact portions 190 may be connected to at least one gate electrode 130 in the connection region 104. A cell insulating layer 132a may be positioned on the gate contact portions 190. The cell insulating layer 132a may include an insulation layer formed on and/or around the gate stack structure 120.

Referring to FIG. 1, the gate contact portions 190 may be positioned in connection regions 104a, 104b, 104c, and 104d of each of the blocks BLK. In the present disclosure, the gate contact portions 190 positioned within the first, second, third, and fourth connection regions 104a, 104b, 104c, and 104d are referred to as a first gate contact portion 190a, a second gate contact portion 190b, a third gate contact portion 190c, and a fourth gate contact portion 190d, respectively.

The gate contact portions 190 may be spaced apart from each other within the connection region 104. The gate contact portions 190 may be arranged apart from each other along the first direction X and the second direction Y within the connection region 104. Referring to FIG. 1, the gate contact portions 190 may be arranged in a zigzag manner along the first direction X and in a line along the second direction Y. Specifically, the gate contact portions 190 may be arranged continuously within the connection region 104 in a honeycomb shape. However, the arrangement of the gate contact portions 190 within the connection region 104 is not limited thereto, and may be changed in various ways.

In some embodiments, a number of gate contact portions 190 included in each of the blocks BLK1 to BLK4 may be the same. For example, the number of gate contact portions 190 included in each of the first connection region 104a, the second connection region 104b, the third connection region 104c, and the fourth connection region 104d may be substantially the same. In another embodiment, the number of gate contact portions 190 included in each of the blocks BLK1 to BLK4 may be different.

The gate contact portions 190 may be arranged regularly within the connection region 104. In some embodiments, the gate contact portions 190 may be regularly arranged throughout an entire region of the connection region 104. In some embodiments, a distance between one gate contact portion (190) and other gate contact portions (190) closest thereto may be constant. For example, referring to FIG. 1, one gate contact portion 190 may be adjacent to six gate contact portions 190 in the second direction Y or diagonal direction (e.g., diagonal direction between and intersecting the first direction X and the second direction Y), and distances between one gate contact portion 190 and six gate contact portions 190 adjacent thereto may be substantially the same.

In some embodiments, the gate contact portions 190 may be arranged at regular intervals throughout the connection regions 104a, 104b, 104c, and 104d. For example, the distance between one gate contact portion 190 and an adjacent gate contact portion 190 included in the same connection region 104 may be substantially the same as the distance between that gate contact portion 190 and an adjacent gate contact portion 190 included in another connection region 104. The adjacent gate contact portion 190 may indicate a gate contact portion 190 positioned at a minimum distance from the gate contact portion 190.

Specifically, in FIG. 1, for a first gate contact portion 190p included in the first connection region 104a and positioned adjacent to the second separation pattern 166, a distance d1 between the first gate contact portion 190p and another first gate contact portion 190a adjacent thereto may be substantially the same as a distance d2 between the first gate contact portion 190p and the second gate contact portion 190b adjacent thereto.

In some embodiments, at least some of the gate contact portions 190 may be arranged at different intervals. For example, the distance between one gate contact portion 190 and another gate contact portion 190 adjacent thereto in the diagonal direction, and the distance between one gate contact portion and another gate contact portion 190 adjacent thereto in the second direction Y may be different. For example, the distance between one gate contact portion 190 and another gate contact portion 190 adjacent thereto in the diagonal direction may be longer or shorter than the distance between one gate contact portion 190 and another gate contact portion 190 adjacent thereto in the second direction Y.

In some embodiments, at least some of the gate contact portions 190 may at least partially overlap at least some regions of the first separation pattern 164 in the second direction Y. Referring to FIG. 1, some of the first gate contact portions 190a and the second gate contact portions 190b positioned adjacent to the second separation pattern 166 positioned between the first block BLK1 and the second block BLK2 may at least partially overlap some regions in the second direction Y with the first separation pattern 164 positioned between the first block BLK1 and the second block BLK2.

In some embodiments, the connection region 104 may include a region in which the number of gate contact portions 190 included in one connection region 104 and the number of gate contact portions 190 included in another connection region 104 are different from each other among gate contact portions 190 arranged in a row along the first direction X across two or more different connection regions 104. For example, when the gate contact portions 190 are arranged in a zigzag manner along the first direction X, as the gate contact portions 190 are regularly arranged throughout the connection region 104, in a region R1 illustrated in FIG. 1, the number of second gate contact portions 190b of the second connection region 104b and the number of third gate contact portions 190c of the third connection region 104c arranged in a row along the first direction X may be different from each other.

In some embodiments, the connection region 104 may include a region in which the number of gate contact portions 190 included in one connection region 104 and the number of gate contact portions 190 included in another connection region 104 are the same as each other among gate contact portions 190 arranged in a row along the first direction X across two or more different connection regions 104. For example, in a region R2 illustrated in FIG. 1, the second separation pattern 166 between the first connection region 104a and the second connection region 104b may extend in the diagonal direction (e.g., extends diagonally between the first direction X and the second direction Y). In this case, any one of the gate contact portions 190 overlapping at least a portion of the first separation pattern 164 in the second direction Y may be included in the second connection region 104b. Accordingly, as in the region R2 of FIG. 1, the number of second gate contact portions 190b and third gate contact portions 190c arranged in a row along the first direction X may be the same.

A semiconductor device according to some embodiments may include a plurality of support structures 162 included in the connection region 104. The support structures 162 may physically support the gate stack structure 120 such that it does not collapse. The support structures 162 may extend through the gate stack structure 120 in the third direction Z around the gate contact portions 190.

Although a shape of the support structures 162 is illustrated to have a circular shape in FIG. 1 in a plan view, the embodiments are not limited thereto, and the shape of the support structures 162 in a plan view may be variously changed. For example, the shape of the support structures 162 may have a polygonal shape in a plan view.

Referring to FIG. 1, the support structures 162 may be spaced apart from each other in the first direction X and the second direction Y. The distances at which the support structures 162 are spaced from each other within the connection region 104 may be constant or may be different. Referring to FIG. 1, the support structures 162 may surround or extend around each of the gate contact portions 190. In FIG. 1, three support structures 162 are illustrated as surrounding or extending around one gate contact portion 190, but the embodiment is not limited to the number of support structures 162 surrounding or extending around one gate contact portion 190, and the number of support structures 162 surrounding or extending around one gate contact portion 190 may be designed in various ways. In some embodiments, the distance between the support structures 162 surrounding or extending around one gate contact portion 190 may be constant. In some embodiments, the distance between the support structures 162 surrounding or extending around one gate contact portion 190 may be different. Referring to FIG. 1, the support structures 162 are illustrated as being arranged in a row or in a zigzag pattern within the connection region 104, but a manner in which the support structures 162 are arranged in a plan view are not limited. Each of the support structures 162 may have a portion in contact with the gate contact portion 190. However, without being limited thereto, each of the support structures 162 may be spaced apart from the gate contact portion 190 by a predetermined distance. In some embodiments, the support structure 162 may be formed together with the second separation pattern 166 to be described later in a same process. A specific structure of the support structure 162 will be described later.

A semiconductor device according to some embodiments may include a plurality of gate through structures 146 included in the connection region 104. The gate through structures 146 may be regions filled with or including holes formed in the gate stack structures 120 to form gate electrodes 130 in a manufacturing process for a semiconductor device according to some embodiments. The gate through structures 146 may extend through or into the gate stack structure 120 in the third direction Z. In some embodiments, the gate through structures 146 may have slanted or sloped side surfaces such that the width becomes narrower as they get closer to the second substrate 110, depending on the aspect ratio in a cross-sectional view.

Although a shape of the gate through structures 146 is illustrated to have a circular shape in FIG. 1 in a plan view, the embodiments are not limited thereto, and the shape of the gate through structures 146 in a plan view may be variously changed. For example, the shape of the gate through structures 146 may have a polygonal shape in a plan view.

Referring to FIG. 1, the gate through structures 146 may be spaced apart from each other in the first direction X and the second direction Y. The distances at which the gate through structures 146 are spaced from each other within the connection region 104 may be constant or may be different. Referring to FIG. 1, the gate through structures 146 are illustrated as being arranged in a row or in a zigzag pattern within the connection region 104, but a manner in which the gate through structures 146 are arranged in a plan view are not limited. For example, the gate through structures 146 may be arranged in a matrix shape or a hexagonal shape. In some embodiments, the gate through structures 146 may be spaced apart from the gate contact portions 190. Specifically, referring to FIG. 1, the gate through structures 146 included in each of the connection regions 104a, 104b, 104c, and 104d may be spaced apart from the gate contact portions 190a, 190b, 190c, and 190d included in each of the connection regions 104a, 104b, 104c, and 104d. In some embodiments, the gate through structures 146 may be formed together with the first separation pattern 164 to be described later in a same process. A specific structure of the gate through structures 146 will be described later.

The semiconductor device according to some embodiments may further include a string connection region 106 positioned between the cell array region 102 and the connection region 104. The string connection region 106 may be a region for connecting string selection transistors, which will be described later with reference to FIG. 35, among a plurality of transistors positioned in the cell array region 102, to peripheral circuits positioned in the circuit region 200.

Referring to FIG. 1, a plurality of selection gate contact portions 193 and a plurality of support structures 162 may be positioned in the string connection region 106. In some embodiments, the string connection region 106 may be spaced apart from the cell array region 102 in the second direction Y with a boundary region 103c therebetween.

A size of the selection gate contact portions 193 positioned in the string connection region 106 in a plan view may be smaller than a size of the gate contact portions 190 positioned in the connection region 104, but the embodiments are not limited thereto. In some embodiments, the selection gate contact portions 193 of the string connection region 106 may extend through or into at least some of the gate electrodes 130 and interlayer insulating layers 132 included in the gate stack structure 120 in the third direction Z. Each of the selection gate contact portions 193 positioned in the string connection region 106 may be connected to at least one of the gate electrodes 130 included in the gate stack structure 120 and connected to gates of the string selection transistors included in the cell array region 102. An arrangement of the selection gate contact portions 193 positioned in the string connection region 106 in a plan view is similar to the gate contact portions 190 included in the connection region 104, so a detailed description will be omitted.

A plurality of support structures 162 positioned in the string connection region 106 may physically support the gate stack structures 120 positioned in the string connection region 106 so as not to collapse. A size of each of the support structures 162 positioned in the string connection region 106 may be smaller than a size of the support structures 162 positioned in the connection region 104 in a plan view, but the embodiments are not limited thereto. In some embodiments, the support structures 162 of the string connection region 106 may extend through or into the gate stack structure 120 in the third direction Z. An arrangement of the support structures 162 positioned in the string connection region 106 in a plan view is similar to the support structures 162 included in the connection region 104, so a detailed description will be omitted.

The semiconductor device according to some embodiments may further include upper separation regions 148 positioned between the channel structures CH. The upper separation regions 148 may extend through or into at least a portion of the gate stack structure 120. For example, referring to FIG. 2, the upper separation regions 148 may extend through or into some of the gate electrodes 130 and interlayer insulating layers 132, which are alternately stacked and are positioned at an upper portion thereof. The upper separation regions 148 may extend in the second direction Y.

The upper separation regions 148 may be spaced apart from each other along the first direction X. Referring to FIGS. 1 and 2, channel structures CH arranged in a row along the second direction Y may be arranged in four rows each along the first direction X between the upper separation regions 148, but the embodiments are not limited thereto. In some embodiments, the upper separation region 148 may extend to the string connection region 106. In the string connection region 106, the gate contact portions 190 and the support structures 162 may be positioned between the upper separation regions 148 arranged in the first direction X. Numbers of gate contact portions 190 and support structures 162 positioned between the upper separation regions 148 may not be limited to the embodiments described herein. First ends of the upper separation regions 148 may be connected to each other at a first edge of the string connection region 106.

The upper separation regions 148 may include an insulating material. For example, the upper separating region 148 may include an insulating material such as a silicon oxide, a silicon nitride, or a silicon oxynitride. However, the embodiments are not limited thereto, and the structure, shape, and material of the upper separating region 148 may be variously modified.

The separation patterns 164 and 166 may be positioned between the blocks BLK1 to BLK4 arranged in the first direction X. The separation patterns 164 and 166 may be positioned in a boundary region 103b between the blocks BLK1 to BLK4. Referring to FIG. 1, the cell region 100 may be divided into the blocks BLK1 to BLK4 by the separation patterns 164 and 166. In some embodiments, the cell array region 102 and the connection region 104 included in one block BLK may be separated from the cell array region 102 and the connection region 104 of another block BLK by the separation patterns 164 and 166.

The first separation pattern 164 may be positioned between the cell array regions 102. The first separation pattern 164 may be positioned between the cell array regions 102 included in each of the blocks BLK1 to BLK4. The first separation pattern 164 may extend in the second direction Y. In some embodiments, the first separation pattern 164 may extend to the string connection region 106. Referring to FIG. 1, the first separation pattern 164 may be connected at a first end to the second separation pattern 166 at a boundary region 103a between the string connection region 106 and the connection region 104.

Referring to FIG. 1, the first separation pattern 164 may have a line shape extending in the second direction Y. A side surface of the first separation pattern 164 may have an embossing shape including a convex portion and a concave portion in a plan view. In some embodiments, the first separation pattern 164 may be formed together with the gate through structures 146 in a same process. In some embodiments, in the first separation pattern 164, some regions of the gate through structures 146 may be arranged to at least partially overlap each other along the second direction Y.

In some embodiments, the first separation pattern 164 may have a maximum width substantially equal to that of the gate through structure 146 along the first direction X. In some embodiments, the first separation pattern 164 may have slanted or sloped side surfaces such that the width becomes narrower as they get closer to the second substrate 110, depending on the aspect ratio in a cross-sectional view.

The first separation pattern 164 may include an insulating material. For example, the first separation pattern 164 may include an insulating material such as a silicon oxide, a silicon nitride, or a silicon oxynitride. However, the embodiments are not limited thereto, and the separation structure 146 may include various insulating materials. In some embodiments, the first separation pattern 164 may include an insulating material that is identical to that of the gate through structure 146.

The second separation pattern 166 may be positioned between the connection regions 104. The second separation pattern 166 may be positioned between the connection regions 104 included in each of the blocks BLK1 to BLK4. Referring to FIG. 1, the second separation pattern 166 may include a line shape extending in the second direction Y or the diagonal direction (e.g., extends diagonally between the first direction X and the second direction Y). A side surface of the second separation pattern 166 may have an embossing shape including a convex portion and a concave portion in a plan view. In some embodiments, in the second separation pattern 166, which will be described later, some regions of the support structures 162 may be arranged to at least partially overlap each other along the second direction Y. In some embodiments, a maximum width of the second separation pattern 166 along a direction intersecting a direction in which the second separation pattern 166 extends may be substantially the same as a maximum width of the support structure 162 along the first direction X.

In some embodiments, the second separation pattern 166 may include a portion extending in the diagonal direction (e.g., extends diagonally between the first direction X and the second direction Y) in a plan view.

For example, the second separation pattern 166 may include a portion in which the second separation pattern 166 extends in the diagonal direction (e.g., diagonally between the first direction X and the second direction Y) in the boundary region 103a between the string connection region 106 and the connection region 104. In a semiconductor device according to some embodiments, the gate contact portions 190 are arranged at a constant distance throughout the connection region 104, so some of the first separation pattern 164 and the gate contact portions 190 may partially overlap each other in the second direction Y. Specifically, referring to FIG. 1, when some of the first separation pattern 164 and the gate contact portions 190 overlap in a regions in the second direction Y, such as in the boundary region 103b between the first block BLK1 and the second block BLK2, in a region where the boundary region 103b between the first block BLK1 and the second block BLK2 and the boundary region 103a between the string connection region 106 and the connection region 104 intersect, the first separation pattern 164 may extend in a diagonal direction (e.g., extends diagonally between the first direction X and the second direction Y). In some embodiments, the second separation pattern 166 may include a region in contact with the gate contact portion 190.

The second separation pattern 166 may extend in the connection region 104 such that each of the connection regions 104a, 104b, 104c, and 104d may include a predetermined number of gate contact portions 190. As an example, the second separation patterns 166 may extend such that each of the connection regions 104a, 104b, 104c, and 104d may include a same number of gate contact portions 190. For example, the gate contact portions 190 that at least partially overlap the first separation pattern 164 in the second direction Y or are arranged in a row along the second direction Y around a boundary between the connection regions 104a, 104b, 104c, and 104d may extend such that some of the two adjacent blocks BLK are included in one block BLK and some are included in the other block BLK.

For example, in a region R3 illustrated in FIG. 1, the second separation pattern 166 may extend in a diagonal direction (e.g., extends diagonally between the first direction X and the second direction Y) such that the second block BLK2 includes a region protruding or extending in the first direction X, and at least one gate contact portion 190 may be positioned in the protruding region. For example, in a region R4 illustrated in FIG. 1, the second separation pattern 166 may extend in a diagonal direction (e.g., extends diagonally between the first direction X and the second direction Y) such that the third block BLK3 includes a region protruding or extending in a direction opposite to the first direction X, and at least one gate contact portion 190 may be positioned in the protruding region.

In this way, the second separation pattern 166 may extend such that the gate contact portions 190 arranged in a row along the second direction Y around a boundary between the connection regions 104a, 104b, 104c, and 104d are divided and included in two adjacent blocks, and accordingly, a same number of gate contact portions 190 may be designed to be included in each of the connection regions 104a, 104b, 104c, and 104d.

According to some embodiments, gate contact portions 190 may be arranged with improved efficiency without wasting space in the entire connection region 104, and accordingly, a width of the entire connection region 104 along the second direction Y may be reduced, and a size of the semiconductor device according to the embodiments may be reduced.

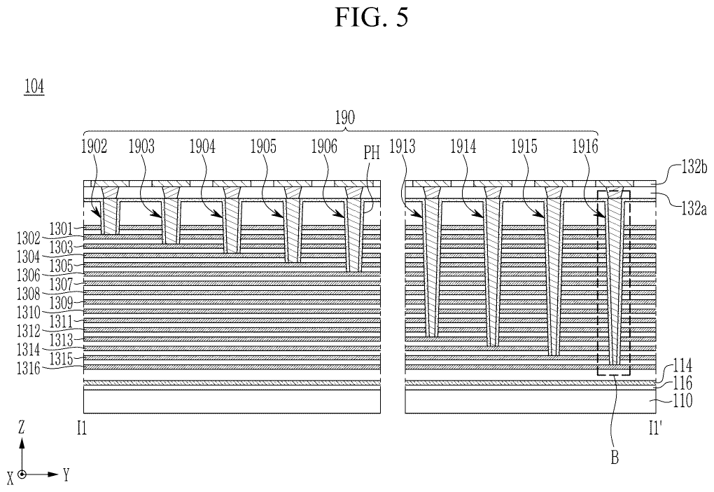

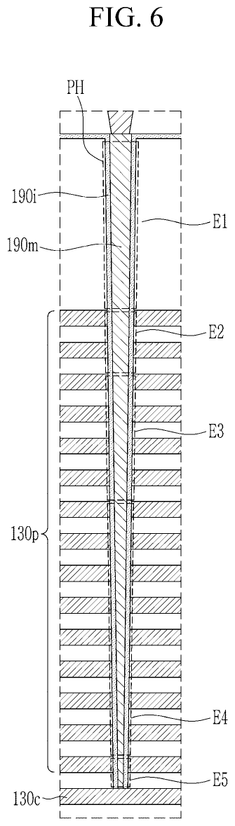

Referring to FIGS. 5 and 6 together with FIG. 3, a connection structure of the gate contact portions 190 and the gate electrodes 130 is described in detail. FIG. 5 illustrates a cross-sectional view showing the connection region 104 of the cell region 100 included in the semiconductor device 10 illustrated in FIG. 3. FIG. 6 illustrates a cross-sectional view of a portion “B” of FIG. 5.

Referring to FIGS. 3, 5, and 6, the gate contact portions 190 may extend through or into a portion of the gate stack structure 120 in the connection region 104, and may be electrically connected (e.g., in contact) to the gate electrodes 130, respectively.

In some embodiments, each of the gate contact portions 190 may extend downward from an upper surface of the gate stack structure 120 toward the lower surface, and may extend through or into a portion of the gate stacked structure 120 in a direction intersecting the second substrate 110 (e.g., a vertical direction perpendicular to the second substrate /110) (e.g., Z-axis direction in the drawing). Herein, an upper surface of the gate stack structure 120 may indicate a surface positioned toward or adjacent the second wiring portion 180 in the vertical direction, and a lower surface of the gate stack structure 120 may indicate a surface opposite to the second wiring portion 180 in the vertical direction or a surface positioned toward or adjacent the second substrate 110. Unless otherwise stated, in relation to the cell region 100 in this specification, the upper or upper surface may indicate a portion or surface positioned at or adjacent a side of the second wiring portion 180, and the lower or lower surface may indicate a portion or surface opposite to the second wiring portion 180, or a portion or surface positioned at or adjacent a side of the second substrate 110.

Each of the gate contact portions 190 may extend through or into a portion of the gate stack structure 120 to a depth sufficient to reach or contact a connection gate electrode 130c among the gate electrodes 130. The gate contact portions 190 may be provided to be respectively connected to the gate electrodes 130. The gate electrodes 130 are positioned at different heights relative to the upper surface of the second substrate 110 in the vertical direction (Z-axis direction in the drawing), and the gate contact portions 190 may have different depths such that they can each reach or contact the gate electrodes 130.

For example, in FIG. 5, gate contact portions 1902, 1903, 1904, 1905, and 1906 may be electrically connected to gate electrodes 1302, 1303, 1304, 1305, and 1306, respectively. For example, in FIG. 5, gate contact portions 1913, 1914, 1915, and 1916 may be electrically connected to gate electrodes 1313, 1314, 1315, and 1316, respectively. Although not explicitly shown in FIG. 5, for example, gate contact portions 1907, 1908, 1909, 1910, 1911, and 1912 may be electrically connected to gate electrodes 1307, 1308, 1309, 1310, 1311, and 1312, respectively. Although not explicitly shown in FIGS. 3, 5 and 6, at least some of the gate electrodes 130 may be connected to at least some of selection gate contact portions 193 in the string connection region 106 described with reference to FIG. 1. For example, in FIG. 5, a first gate electrode 1301 may be connected to the selection gate contact portion 193 in the string connection region 106 described with reference to FIG. 1. This is merely an example, and two or more gate electrodes 130 among the gate electrodes 130 may be connected to the selection gate contact portion 193 in the string connection region 106.

In the drawing, the gate electrode 130 is illustrated as including the gate electrodes 1301 to 1316, and the gate contact portion 190 is illustrated as including the gate contact portions 1902 to 1916. In this case, the gate contact portions 1902 to 1906 may be electrically connected to the gate electrodes 1302 to 1306, respectively, the gate contact portions may be electrically connected to the gate electrodes 1307 to 1312, respectively, and the gate contact portions 1913 to 1916 may be electrically connected to the gate electrodes 1313 to 1316, respectively. In this way, the gate contact portions 190 may be electrically connected to the gate electrodes 130.

For clear understanding and simple illustration, the drawing illustrates that depths of the gate contact portions 190 is sequentially increased as they move away from the cell array region 102, but the embodiments are not limited thereto. An arrangement of the gate contact portions 190 may be varied in various ways.

Based on one gate contact portion 190, the gate electrodes 130 may include a connection gate electrode 130c electrically connected to one gate contact portion 190, and may include a through gate electrode 130p and/or remaining gate electrodes. The through gate electrode 130p may correspond to the gate electrode 130 positioned on the connection gate electrode 130c as the gate electrode 130 that extends through or into the gate contact portion 190 but is electrically insulated from the gate contact portion 190 by a side wall insulating layer 190i of the gate contact portion 190. The remaining gate electrode may correspond to the gate electrode 130 positioned below the connection gate electrode 130c as the gate electrode that is not penetrated or extended into by the gate contact portion 190 and is electrically insulated from the gate contact portion 190.

In the gate contact portion 1902, the second gate electrode 1302 may correspond to the connection gate electrode 130c, and the gate electrode 130 positioned below the connection gate electrode 130c may correspond to the remaining gate electrode. In some embodiments, each of the gate contact portions 190 may be electrically connected (e.g., in contact) to the upper surface of the connection gate electrode 130c. However, the embodiments are not limited thereto. Each of the gate contact portions 190 may be electrically connected (e.g., in contact) to a different portion (e.g., a side surface) of the connection gate electrode 130c.

In some embodiments, each of the gate contact portions 190 may include a conductive portion 190m and a sidewall insulating layer 190i positioned between the conductive portion 190m and the gate stack structure 120.

In each of the gate contact portions 190, the sidewall insulating layer 190i may be positioned between at least the side surface of the conductive portion 190m and the side surface of the through gate electrode 130p to electrically insulate the conductive portion 190m and the through gate electrode 130p. The sidewall insulating layer 190i may not be positioned on a lower surface of the conductive portion 190m and an upper surface of the connection gate electrode 130c. That is, the sidewall insulating layer 190i may not be positioned between an upper surface of the connection gate electrode 130c and a lower surface of the gate contact portion 190. For example, the lower surface of the sidewall insulating layer 190i may be in contact with the connection gate electrode 130c, or may be positioned between the upper and lower surfaces of the interlayer insulating layer 132 positioned on the connection gate electrode 130c.

Accordingly, the sidewall insulating layer 190i may surround or extend around the entire side surface of the gate contact portion 190, and may stably insulate the gate contact portion 190 and the through gate electrode 130p from each other. However, the embodiments are not limited thereto, and a position of the sidewall insulating layer 190i, a connection position of the gate contact portion 190 and the connection gate electrode 130c, etc. may be modified in various ways.

For example, the conductive portion 190m may have a columnar shape (e.g., a columnar shape having a circular or polygonal planar shape), and the sidewall insulating layer 190i may have various planar shapes, such as an annular shape, a ring shape, or a frame shape, surrounding or extending around the conductive portion 190m.

In the drawing, it is illustrated that the gate contact portion 190 or conductive portion 190m has an inclined or sloped side surface such that the width becomes narrower as it approaches the second substrate 110 according to an aspect ratio when viewed in cross-section. However, the embodiments are not limited thereto, and the shape, structure, etc. of the gate contact portion 190 or the conductive portion 190m may be modified in various ways.

In some embodiments, the gate contact portion 190 positioned inside a through hole PH may be electrically connected to an upper portion of the connection gate electrode 130c. For example, a plurality of through holes PH individually extending through the gate stack structure 120 and spaced apart with the gate stack structure 120 provided therebetween may be included, one gate contact portion 190 may be positioned in one through hole PH, and a lower surface of the conductive portion 190m of one gate contact portion 190 positioned inside one through hole PH may be positioned (e.g., in contact with) on an upper surface of the connection gate electrode 130c. For example, a plurality of gate contact portions 190 may be positioned within the through holes PH that are spaced apart from each other so as to correspond one-to-one to the gate contact portions 190. In some embodiments, the through hole PH may have various planar shapes such as a circle, a polygon, an ellipse, etc., and the embodiment is not limited to the planar shape of the through hole PH.

Accordingly, a pad region (e.g., a pad insulating layer) through which the gate contact portions 190 pass or extend into together, or a separate insulating layer (e.g., a pad insulating layer) positioned between the gate contact portions 190 other than the interlayer insulating layer 132, or a portion where a part of the gate stack structure 120 is removed for electrical connection of the gate contact portions 190 (e.g., a portion having a step shape) may be omitted. That is, the gate contact portions 190 may be individually electrically connected to the gate electrodes 130 without a pad region or pad insulating layer. Accordingly, the process of electrically connecting the gate contact portion 190 and the gate electrode 130 may be simplified and an area of the connection region 104 may be reduced.

In contrast, in a comparative example including a pad region, a process of etching a portion of the gate stacked structure (e.g., a process of forming a portion having a step shape), a process of forming a pad insulating layer covering or overlapping the step shape of the gate stack structure, and a process of electrically connecting a plurality of gate contact portions extending through or into one pad insulating layer to a plurality of gate electrodes, respectively, may have to be performed. Accordingly, the process of forming the pad region and the process of forming the gate contact portion may be complex. Furthermore, in order to prevent or inhibit misalignment of the gate contacts in the pad region or pad insulating layer where the gate contact portions penetrate together, a sufficient width may have to be secured between the gate contact portions. Accordingly, an area of the connection region may increase.

The conductive portion 190m may include, e.g., tungsten (W), copper (Cu), aluminum (Al), etc., and may further include a diffusion barrier layer. However, the embodiments are not limited to the material of the conductive portion 190m.

In this case, in an etching process for forming a through hole PH, the interlayer insulating layer 132 and a layer positioned on an upper portion thereof (e.g., a sacrificial insulating layer) may be etched according to a binary method to form the through hole PH. For example, in a partial etching process, the number of interlayer insulating layers 132 corresponding to 1, 2, 4, . . . , 2^{m-1} and the sacrificial insulating layer positioned at an upper portion thereof may be etched. Herein, m is a natural number greater than 1, and may indicate a total number of partial etching processes. The m^{th} partial etching process is a longest partial etching process that performs the etching process of the greatest depth, and an etching process of a greater depth may be performed than other partial etching processes and the additional etching process E5.

For example, in the first partial etching process E1, one interlayer insulating layer 132 of 2 to the power of 0 may be etched, and in the m^{th} partial etching process, the interlayer insulating layer 132 of 2^{m-1} and a sacrificial insulating layer positioned at an upper portion thereof may be etched.

By repeating the partial etching process according to the binary method in this way, multiple through holes PH with different depths may be formed by performing a small number of etching processes. For example, if the partial etching process according to the binary method is repeated four times, 15 (fifteen) through holes PH having different depths may be formed. If the partial etching process according to the binary method is repeated five times, 31 (thirty-one) through holes PH having different depths may be formed. If the partial etching process according to the binary method is repeated six times, 63 (sixty-three) through holes PH having different depths may be formed. In this way, the number of etching processes may be effectively reduced.

As described above, for the sake of clear understanding and simple illustration, the drawing illustrates 16 (sixteen) gate electrodes 130. In this case, four partial etching processes, i.e., first to fourth partial etching processes E1, E2, E3, and E4 and one additional etching process E5, may be performed to form 16 (sixteen) through holes PH corresponding to 16 (sixteen) gate contact portions 190 and/or selection gate contact portions 193 (see FIG. 1). However, the embodiments are not limited thereto. Accordingly, the number of gate electrodes 130 may be varied, and the number of partial etching processes and/or the number of additional etching processes E5 may be varied.

Unlike what is shown in FIG. 6, the conductive portion 190m may have different widths at boundaries between multiple sections defined by the partial etching processes E1, E2, E3, and E4 and the additional etching process E5. In this case, unlike what is illustrated in FIG. 6, the conductive portion 190m may be provided with a bend or bent portion due to a width difference at the boundary between a plurality of sections defined by the partial etching processes E1, E2, E3, and E4 and the additional etching process E5.

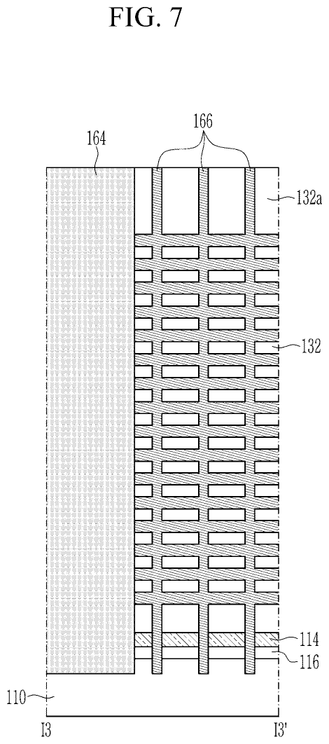

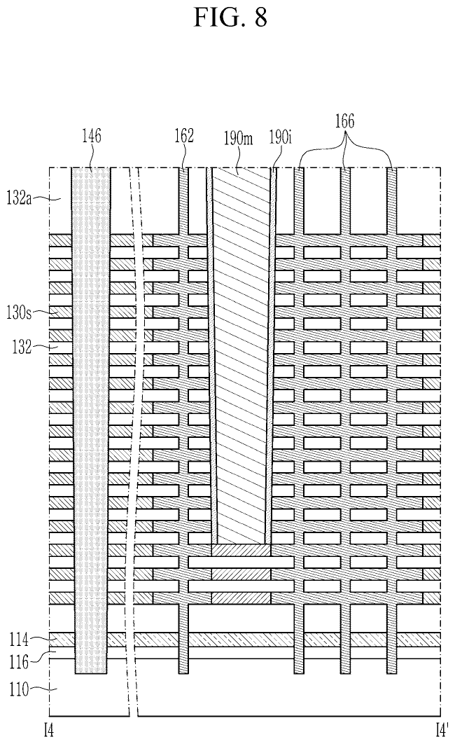

FIGS. 7 and 8 illustrate views for describing structures of a gate through structure 146, a support structure 162, a first separation pattern 164, and a second separation pattern 166 included in a semiconductor device according to some embodiments. Specifically, FIG. 7 illustrates a schematic cross-sectional view taken along a line I3-I3′ of FIG. 1. FIG. 8 illustrates a cross-sectional view of a semiconductor device taken along line I4-I4′ in FIG. 1.

In a semiconductor device according to some embodiments, the gate through structure 146 and the first separation pattern 164 may be formed together in a same process. In some embodiments, the gate through structure 146 and the first separation pattern 164 may be positioned at a same level (or height relative to the lower surface of the second substrate 110 in the Z-axis direction) on the second substrate 110. The gate through structure 146 and the first separation pattern 164 may extend through or into the gate electrodes 130 and the interlayer insulating layers 132, which are stacked in the third direction Z, in the third direction Z. The gate through structure 146 and the first separation pattern 164 may have side surfaces in contact with the gate electrodes 130 and the interlayer insulating layers 132. The gate through structure 146 and the first separation pattern 164 may extend into the second substrate 110 through horizontal conductive layers 112 and 114.

Referring to FIGS. 7 and 8, the gate through structure 146 and the first separation pattern 164 may have a pillar shape. For example, the gate through structure 146 and the first separation pattern 164 may have slanted or sloped side surfaces such that the width becomes narrower as they get closer to the second substrate 110, depending on the aspect ratio in a cross-sectional view. In some embodiments, side surfaces of the gate through structures 146 and the first separation pattern 164 may have a constant inclination or slope with respect to the first direction X and the second direction Y.

In a semiconductor device according to some embodiments, the support structure 162 and the second separation pattern 166 may be formed together in a same process. The support structure 162 and the second separation pattern 166 may be positioned at a same level (or height relative to the lower surface of the second substrate 110 in the Z-axis direction) on the second substrate 110. The support structure 162 and the second separation pattern 166 may extend through or into the gate electrodes 130 and the interlayer insulating layers 132 in the third direction Z. The support structure 162 and the second separation pattern 166 may have their side surfaces in contact with the gate electrodes 130 and the interlayer insulating layers 132. The support structure 162 and the second separation pattern 166 may extend into the second substrate 110 through horizontal conductive layers 112 and 114.

In some embodiments, the support structure 162 and the second separation pattern 166 may have widths along a horizontal direction (e.g., in the first direction X or in the second direction Y) that are not constant along heights thereof. Referring to FIGS. 7 and 8, the support structure 162 and the second separation pattern 166 may each have a wider or larger width in a region horizontally overlapping at least a portion of the gate electrode 130 compared to a width in a region horizontally overlapping at least a portion of the interlayer insulating layer 132.

Specifically, the support structure 162 and the second separation pattern 166 may each include a central portion extending in the third direction Z through or into the gate electrodes 130 and the interlayer insulating layers 132, and a plurality of extensions extending horizontally from the central portion. The extensions may be spaced apart from each other in the third direction Z. Referring to FIGS. 7 and 8, the extensions may be positioned in a region that overlaps at least a portion of the gate electrode 130 in the horizontal direction. The extensions may be positioned at substantially a same level (or height relative to the lower surface of the second substrate 110 in the Z-axis direction) as that of the respective gate electrodes 130 stacked in the third direction Z.

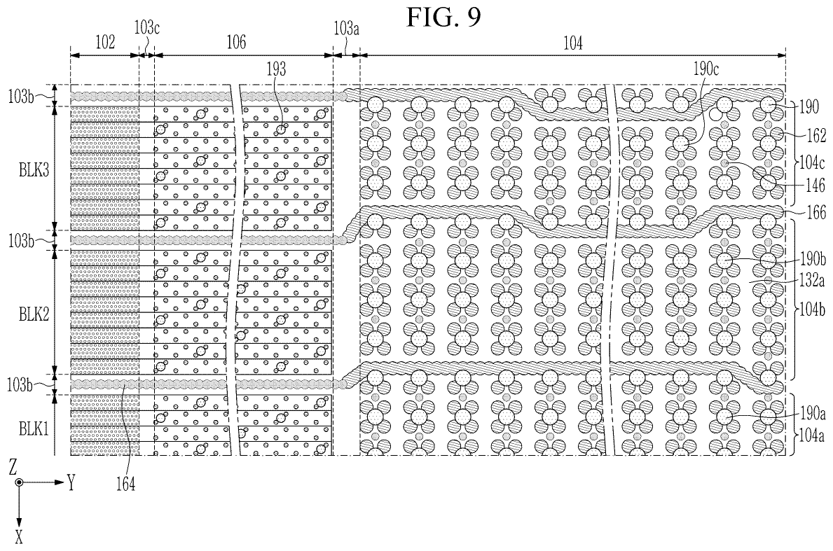

FIG. 9 illustrates a top plan view showing a semiconductor device according to some embodiments.

The semiconductor device illustrated in FIG. 9 is similar to the previous embodiments, so the following description focuses mainly on the differences from the previous embodiments. The semiconductor device illustrated in FIG. 9 may have a different planar arrangement of gate contact portions 190 compared to the previous embodiments.

Unlike in the embodiments described with reference to FIGS. 1 to 8, in the semiconductor device illustrated in FIG. 9, a plurality of gate contact portions 190 positioned in the connection region 104 may be arranged in a matrix form. In some embodiments, the gate contact portions 190 positioned in the connection region 104 may be arranged in a row along the first direction X and the second direction Y. The gate contact portions 190 may be positioned in connection regions 104a, 104b, 104c, and 104d of each of the blocks BLK. Specifically, referring to FIG. 9, the gate contact portions 190 may be regularly arranged throughout an entire region of the connection region 104. In some embodiments, a distance between one gate contact portion 190 and other gate contact portions 190 closest thereto may be constant. For example, referring to FIG. 9, one gate contact portion 190 may be adjacent to four gate contact portions 190 in the first direction X and the second direction Y, and distances between the one gate contact portion 190 and the four gate contact portions 190 adjacent thereto may be substantially the same.

In some embodiments, the gate contact portions 190 may be arranged at regular intervals throughout the connection regions 104a, 104b, 104c, and 104d. For example, the distance between one gate contact portion 190 and an adjacent gate contact portion 190 included in the same connection region 104 may be substantially the same as the distance between that gate contact portion 190 and an adjacent gate contact portion 190 included in another connection region 104. The adjacent gate contact portion 190 may include a gate contact portion 190 positioned at a minimum distance from the gate contact portion 190.

In some embodiments, the connection region 104 may include a region in which the number of gate contact portions 190 included in one connection region 104 and the number of gate contact portions 190 included in another connection region 104 are different from each other among gate contact portions 190 arranged in a row along the first direction X across two or more different connection regions 104.

For example, in some embodiments in which the gate contact portions 190 are arranged in a row along the first direction X illustrated in FIG. 9, the second separation pattern 166 may include a region extending in a diagonal direction (e.g., extends diagonally between the first direction X and the second direction Y), and in this case, the gate contact portions 190 at least partially overlapping the first separation pattern 164 in the second direction Y may be divided and included in two adjacent blocks. Accordingly, the connection region 104 may include a region in which the numbers of second gate contact portions 190b and third gate contact portions 190c arranged in a row along the first direction X are different from each other.

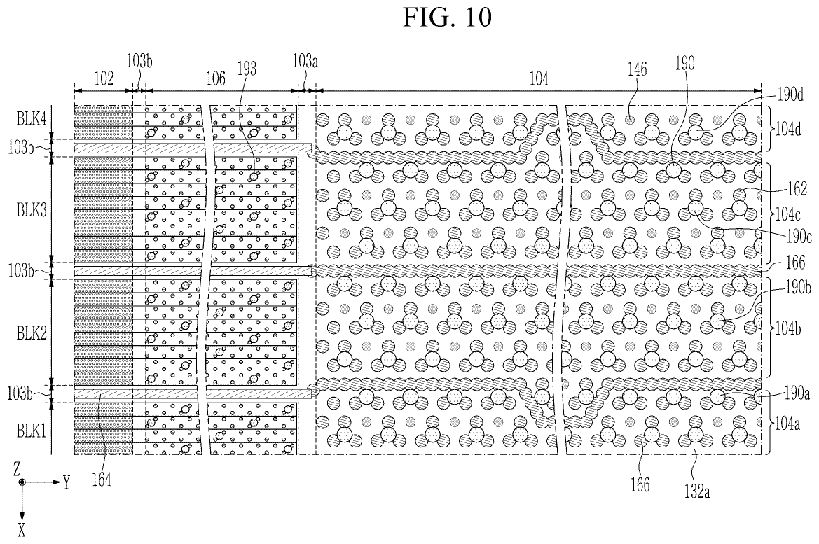

FIG. 10 illustrates a top plan view showing a semiconductor device according to some embodiments.

The semiconductor device illustrated in FIG. 10 is similar to the previous embodiments, so the following description focuses mainly on the differences from the previous embodiments. The semiconductor device illustrated in FIG. 10 may differ from the previous embodiments in some respects in that the first separation pattern 164 is formed together with the gate contact portion 190 in a same process.

In some embodiments, the first separation pattern 164 may extend through or into the gate stack structure 120 (see FIG. 3) in the third direction Z. For example, for the first separation pattern 164, at least a portion of the gate stack structure 120 may be etched together in a process of forming the through hole PH as described with reference to FIGS. 5 and 6. In this case, the gate stack structure 120 may be etched so as to allow a region thereof to be completely penetrated or extended into in the third direction Z. Thereafter, the etched region may be at least partially filled with an insulating material to form the first separation pattern 164.

In some embodiments, the first separation pattern 164 may have a line shape extending along the second direction Y. Referring to FIG. 10, the first separation pattern 164 may have a rectangular shape extending along the second direction Y. A width of the first separation pattern 164 according to the second direction Y may be constant. Although not clearly illustrated in FIG. 10, in some embodiments, the first separation pattern 164 may have slanted or sloped side surfaces such that the width becomes narrower as they get closer to the second substrate 110, depending on the aspect ratio in a cross-sectional view. In some embodiments, the first separation pattern 164 may include an insulating material. For example, it may include at least one of a silicon oxide (SiO₂), a silicon nitride (SiN_{X}), or a silicon oxynitride (SiON). According to some embodiments, a process of forming the first separation pattern 164 may be shortened, so that a cost of the process of manufacturing the semiconductor device according to the embodiment may be reduced.

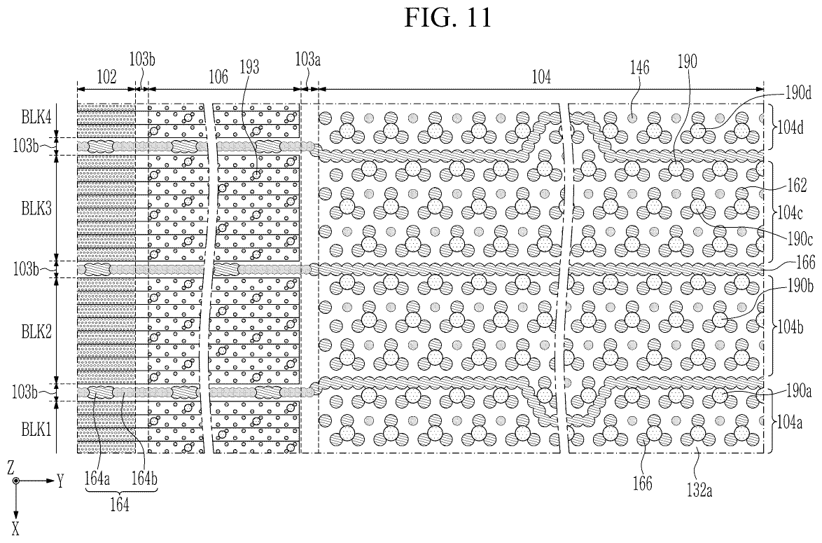

FIG. 11 illustrates a top plan view showing a semiconductor device according to some embodiments.

The semiconductor device illustrated in FIG. 11 is similar to the previous embodiments, so the following description focuses mainly on the differences from the previous embodiments. The semiconductor device illustrated in FIG. 11 may differ from the previous embodiments in some respects in that the first separation pattern 164 includes a first region 164a and a second region 164b.

Referring to FIG. 11, the first separation pattern 164 may include a first region 164a and a second region 164b alternately arranged along the second direction Y. In some embodiments, the first region 164a may be formed together in a same process as that of the support structure 162 and/or the second separation pattern 166, and the second region 164b may be formed together in a same process as that of the gate through structure 146. In some embodiments, the first region 164a may have a cross-section structure similar to that of the support structure 162 and/or the second separation pattern 166, and the second region 164b may have a cross-section structure similar to that of the gate through structure 146. For example, the first region 164a may have the same cross-section structure as that of the support structure 162 or the second separation pattern 166, described with reference to FIG. 7 and FIG. 8, and the second region 164b may have the same cross-section structure as that of the gate through structure 146, described with reference to FIG. 7 and FIG. 8.

According to some embodiments, the first separation pattern 164 may be formed together with the support structure 162 in some regions in a same process, and thus, during a manufacturing process of the semiconductor device according to some embodiments, in the cell array region 102, a gate stack structure 120 (see FIG. 3) having a high aspect ratio may be stably supported without collapsing.

In another embodiment, unlike what is illustrated in FIG. 11, the second region 164b may be formed together with the gate contact portion 190 in a same process. In other words, the first separation pattern 164 may include a first region 164a and a second region 164b that are alternately arranged along the second direction Y, and the second region 164b may have a structure similar to that of the first separation pattern 164 illustrated in FIG. 10. In this case, the second region 164b may have a line shape extending along the second direction Y. In some embodiments, the first region 164a may have a cross-section structure similar to that of the support structure 162 and/or the second separation pattern 166, and the second region 164b may have a cross-section structure similar to that of the gate contact portion 190. For example, the first region 164a may have the same cross-section structure as that of the support structure 162 or the second separation pattern 166, described with reference to FIG. 8, and the second region 164b may have the same cross-section structure as that of the gate contact portion 190, described with reference to and FIG. 8. In some embodiments, the second region 164b may include an insulating material such as a silicon oxide (SiO₂) or a silicon nitride (SiN_{X}), for example.

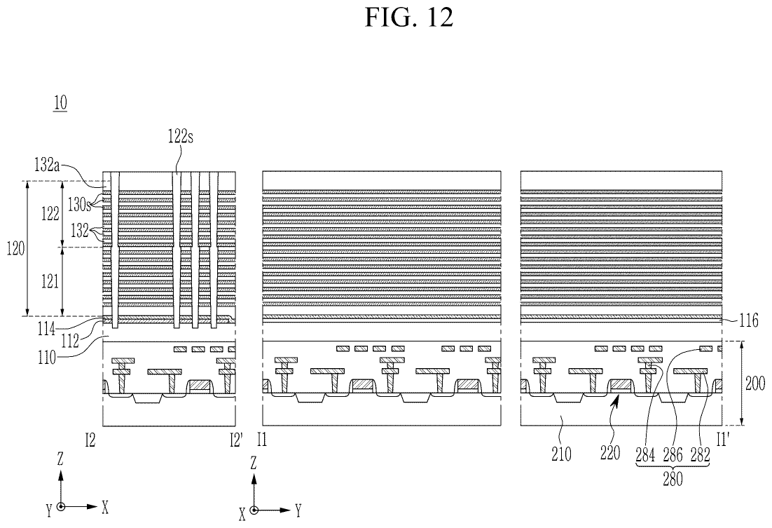

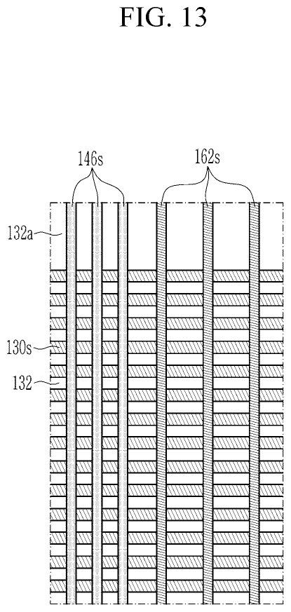

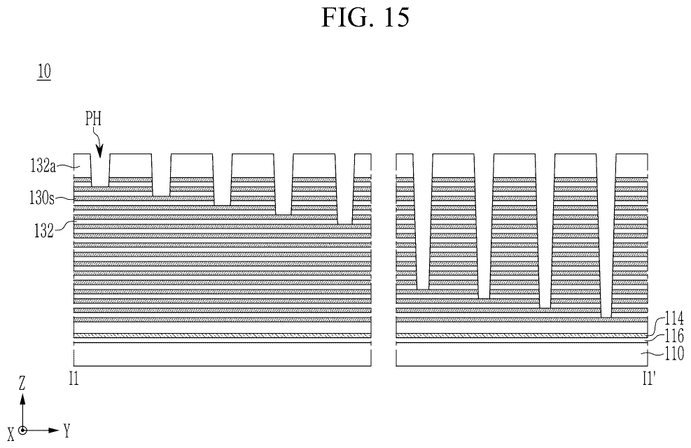

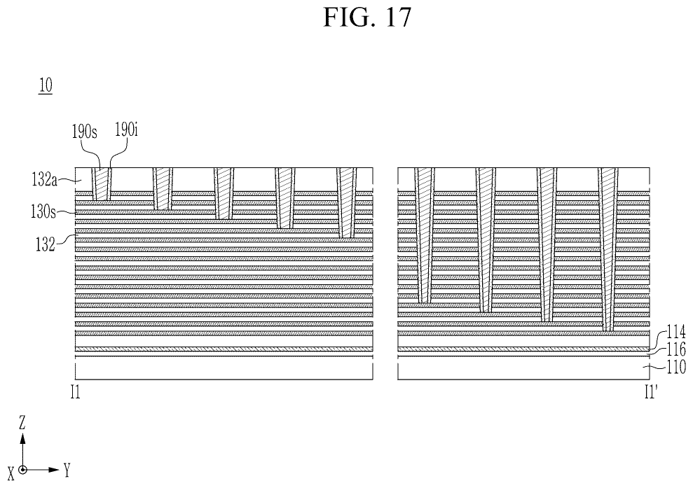

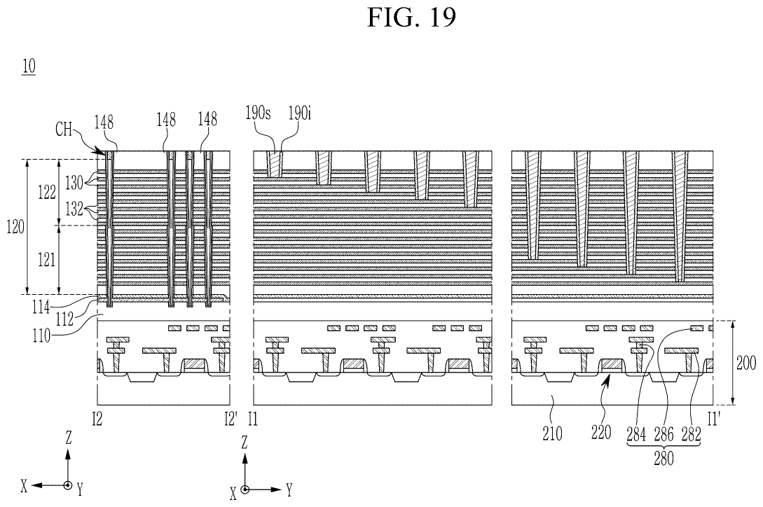

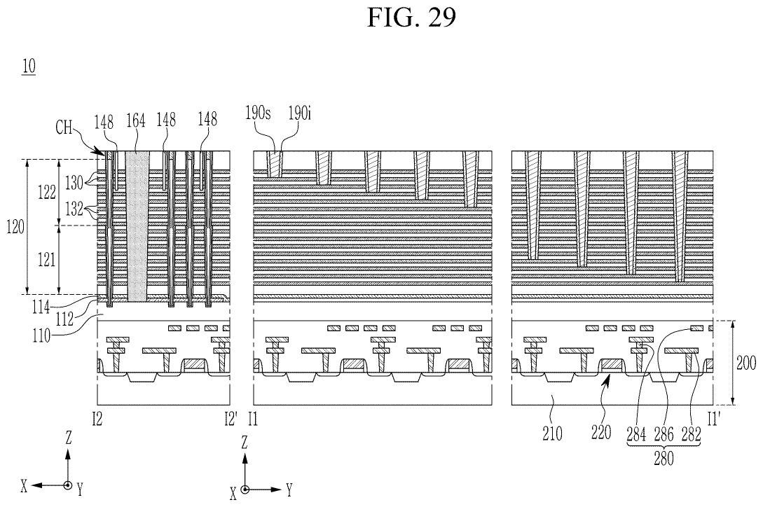

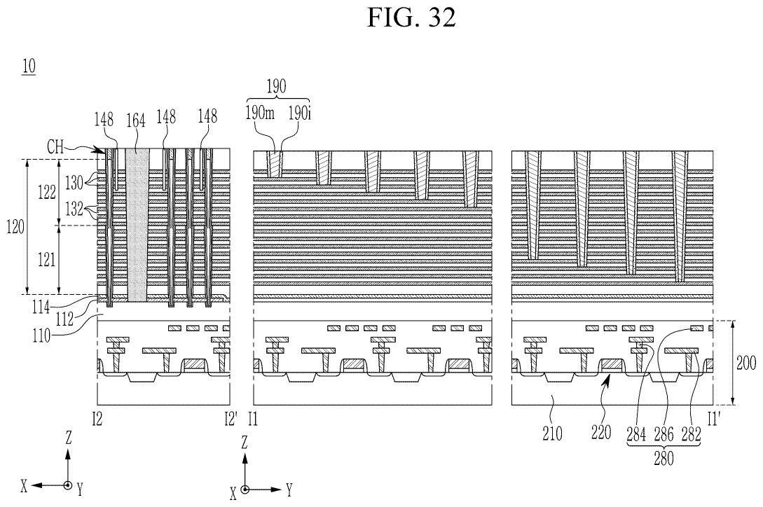

FIG. 12 to FIG. 33 illustrate process cross-sectional views for describing a manufacturing method for a semiconductor package according to some embodiments. FIG. 12, FIG. 15, FIG. 17, FIG. 19, FIG. 29, and FIG. 32 each illustrate a cross-sectional view corresponding to a region taken along line I1-I1′ and/or I2-I2′ of FIG. 3 for describing a manufacturing method for a semiconductor device according to some embodiments.

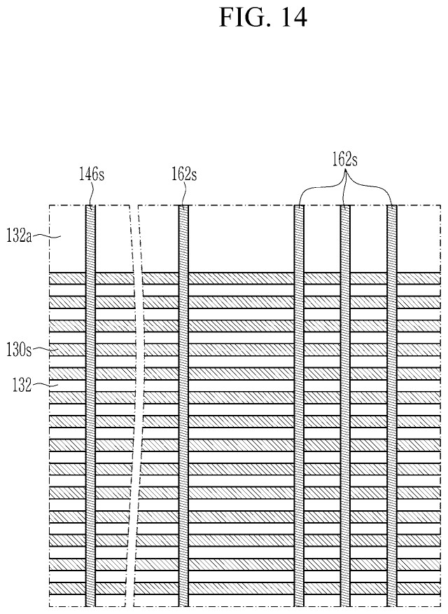

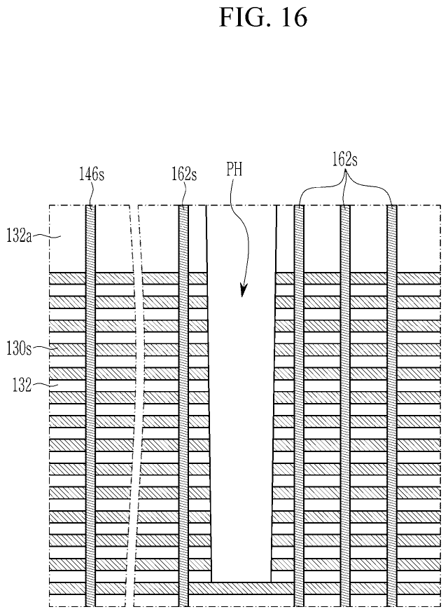

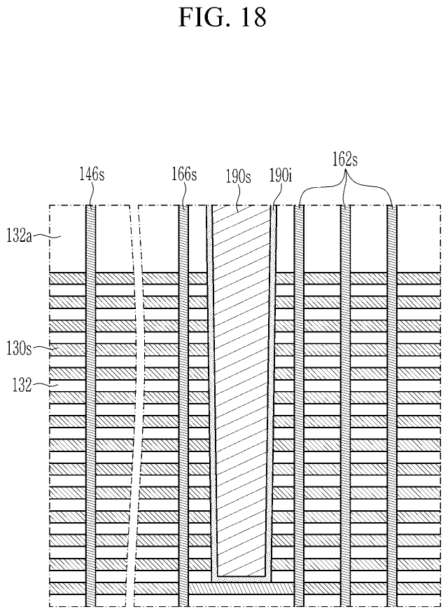

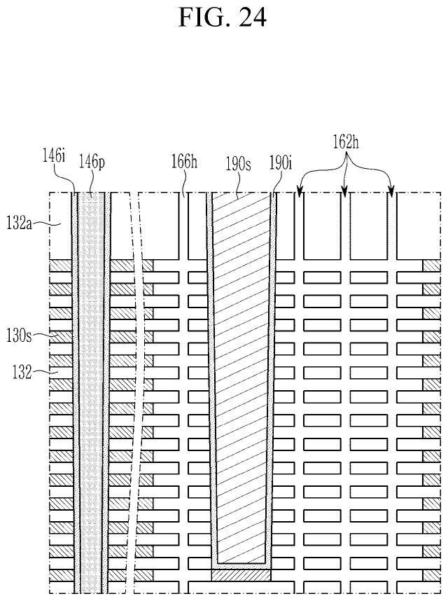

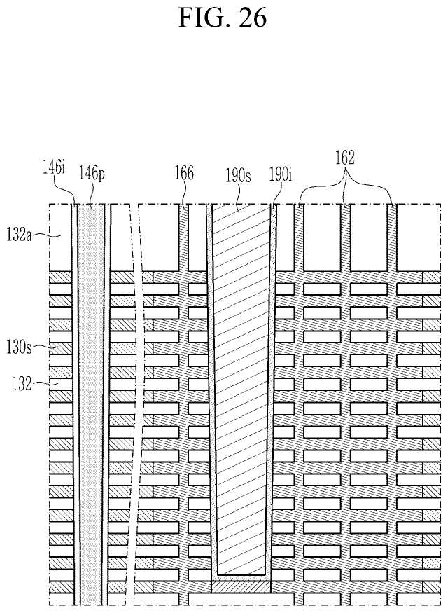

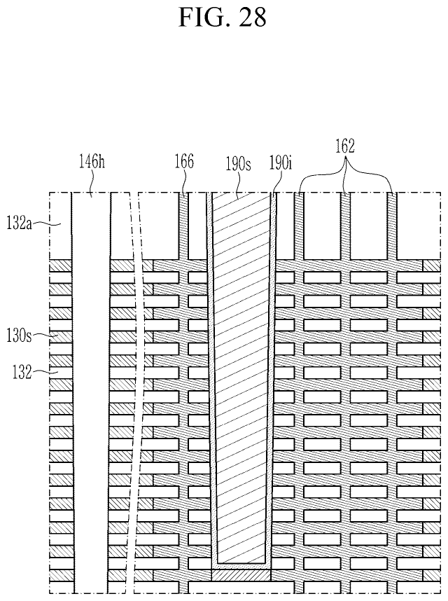

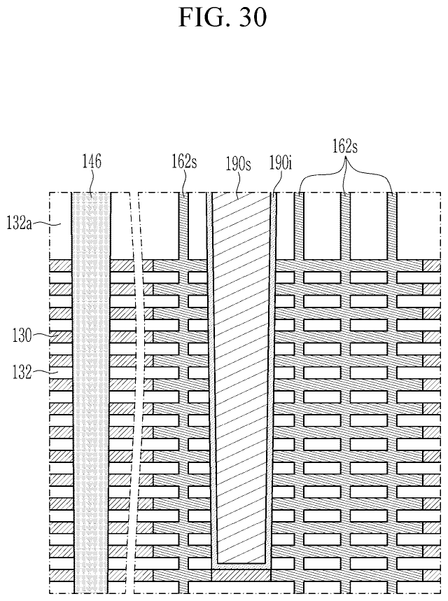

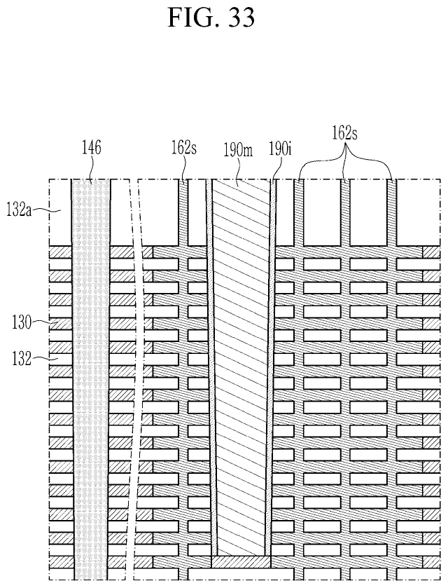

FIG. 14, FIG. 16, FIG. 18, FIG. 24, FIG. 26, FIG. 28, FIG. 30, and FIG. 33 each illustrate a cross-sectional view corresponding to a region taken along line I4-I4′ of FIG. 3 for describing a manufacturing method for a semiconductor device according to some embodiments.

As illustrated in FIGS. 12 to 14, a second substrate 110 and a stack structure 120s are formed on the circuit region 200, and a channel sacrificial layer 122s extending through or into the stack structure 120s, a gate through structure sacrificial layer 146s, and a support structure sacrificial layer 162s may be formed. In this case, after forming a horizontal insulating layer 116 and a second horizontal conductive layer 114 on the second substrate 110, the stack structure 120s may be formed, and the channel sacrificial layer 122s, the gate through structure sacrificial layer 146s, and the support structure sacrificial layer 162s may be formed to extend through or into the stack structure 120s, the horizontal insulating layer 116, and the second horizontal conductive layer 114.

More specifically, the second substrate 110 may be formed on the circuit region 200, and the horizontal insulating layer 116, the second horizontal conductive layer 114, and the stack structure 120s may be formed on the second substrate 110. In this case, an interlayer insulating layer 132 and a sacrificial insulating layer 130s may be alternately stacked to form the stack structure 120s.

Herein, the sacrificial insulating layer 130s may be a layer that is replaced with a gate electrode (reference numeral 130 of FIG. 29, the same hereinafter) through a subsequent process, and may be formed to correspond to a portion where the gate electrode 130 is to be formed. The horizontal insulating layer 116 and/or the sacrificial insulating layer 130s may be formed of a material different from that of the interlayer insulating layer 132. For example, the interlayer insulating layer 132 may include a silicon oxide, a silicon nitride, a silicon oxynitride, a low-k material, etc., and the sacrificial insulating layer 130s may include at least one of silicon, a silicon oxide, a silicon carbide, and a silicon nitride and may be made of a different material from that of the interlayer insulating layer 132.

In some embodiments, the stack structure 120s may be formed in the cell array region 102 and the connection region 104.

A preliminary through portion extending through or into the stack structure 120s may be formed corresponding to a portion where a channel structure (reference symbol CH of FIG. 32, the same hereinafter), the gate through structure (146 of FIG. 30), and the support structure sacrificial layer 162s are to be formed, and a sacrificial material is at least partially filled in the preliminary through portion to form the channel sacrificial layer 122s.

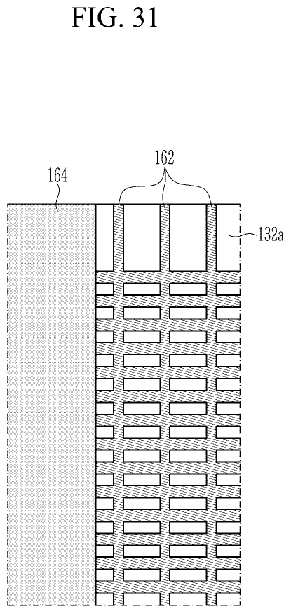

In some embodiments, a preliminary through portion extending through or into the stack structure 120s may be formed corresponding to a portion where a gate through structure (146 of FIG. 30) and a first separation pattern (164 of FIG. 31) are to be formed, and a sacrificial material may be at least partially filled in the preliminary through portion to form a gate through structure sacrificial layer 146s. In some embodiments, a preliminary through portion extending through or into the stack structure 120s may be formed corresponding to a portion where the support structure 162 and the second separation pattern 166 are to be formed, and a sacrificial material may be at least partially filled in the preliminary through portion to form the support structure sacrificial layer 162s.

The preliminary through portion may be formed by an etching process (e.g., a dry etching process), and a process of at least partially filling the preliminary through portion may be performed by various processes (e.g., a deposition process). The channel sacrificial layer 122s, the gate through structure sacrificial layer 146s, and the support structure sacrificial layer 162s may include at least one of polycrystalline silicon, tungsten, titanium nitride, or carbon. However, the embodiments are not limited thereto, and the channel sacrificial layer 122s, gate through structure sacrificial layer 146s, and support structure sacrificial layer 162s may include various materials.

Subsequently, as shown in FIG. 15 and FIG. 16, a plurality of through holes PH for forming a plurality of gate contact portions 190 may be formed by performing a plurality of partial etching processes (e.g., the first to fourth partial etching processes E1, E2, E3, and E4 described with reference to FIGS. 5 and 6) and/or the additional etching process E5).

For the sake of clear understanding and simple illustration, FIGS. 15 and 16 and the description thereof illustrate that there are 16 sacrificial insulating layers 130s and that the first to fourth partial etching processes E1, E2, E3, and E4 and one additional etching process E5 are performed. For better understanding and ease of description, 9 of the 16 through holes PH exposing portions of the 16 sacrificial insulating layers 130s are illustrated in FIGS. 15 and 16. In some embodiments, a number of sacrificial insulating layers 130s may be varied, and a number of partial etching processes E1, E2, E3, and E4 and/or a number of additional etching processes E5 may be varied depending on a number of sacrificial insulating layers 130s.

In some embodiments, a number of interlayer insulating layers 132 (position or level in the vertical direction) positioned on each of the sacrificial insulating layers 130s is converted into binary, and correspondingly, the partial etching processes (e.g., first to fourth partial etching processes E1, E2, E3, and E4) and/or the additional etching process E5 are performed to form the through holes PH having different depths.

The partial etching processes (e.g., the first to fourth partial etching processes E1, E2, E3, and E4) may correspond to a cyclic etching process that forms a mask, performs etching according to a binary method, and then removes the mask. For example, the partial etching processes may form the through holes PH by etching the interlayer insulating layer 132 and a layer positioned at an upper portion thereof (e.g., a sacrificial insulating layer 130s) according to a binary method. For example, in the partial etching process, a number of interlayer insulating layers 132 corresponding to the (m−1)^{th} power of 1, 2, 4, . . . , 2^{m-1}, and the sacrificial insulating layer 130s positioned at an upper portion thereof may be etched. Herein, m is a natural number greater than 1, and may indicate a total number of partial etching processes. The m^{th} partial etching process is a longest partial etching process that performs the etching process of the greatest depth, and an etching process of a greater depth may be performed than other partial etching processes and the additional etching process E5. In some embodiments, the partial etching processes according to a binary method may be used to form the through holes PH, thereby significantly reducing the number of etching processes for forming the through holes PH.

Next, as shown in FIGS. 17 and 18, an interior of the through hole PH (e.g., an inner surface sidewall insulating layer 190i of the through hole PH) may be conformally formed. After forming the sidewall insulating layer 190i, a through sacrificial layer 190s may be formed on an inner surface of the through hole PH. The through sacrificial layer 190s may include at least one of polycrystalline silicon, tungsten, titanium nitride, or carbon. However, the embodiments are not limited thereto, and the through sacrificial layer 190s may include various materials.

Subsequently, as shown in FIG. 19, the channel structure CH may be formed. More specifically, a through portion may be formed by removing the channel sacrificial layer (122s in FIG. 12). A process of forming the through portion may be performed by various etching processes (e.g., dry etching process). In some embodiments, a gate dielectric layer (reference numeral 150 of FIG. 4, the same hereinafter), a channel layer (reference numeral 140 of FIG. 4, the same hereinafter), a core insulating layer (reference numeral 142 of FIG. 4, the same hereinafter) may be sequentially formed in a through portion, and a channel pad (reference numeral 144 of FIG. 4, the same hereinafter) may be formed. A process of forming the gate dielectric layer 150, the channel layer 140, the core insulating layer 142, or the channel pad 144 may be performed by various processes (e.g., a deposition process, etc.).

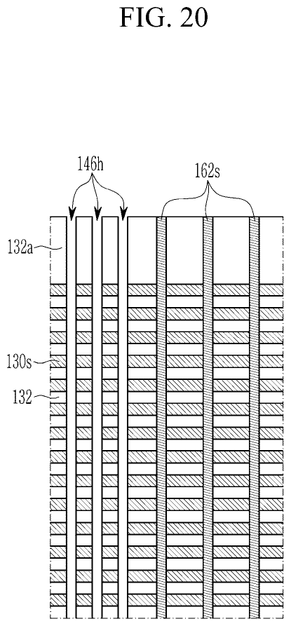

Next, as illustrated in FIG. 20, the gate through structure sacrificial layer 146s may be removed to form a first preliminary through hole 146h. Specifically, the gate through structure sacrificial layer 146s positioned at a portion where the gate through structure 146 is to be formed and a portion where the first separation pattern 164 is to be formed may be removed by an etching process. A process of etching the gate through structure sacrificial layer 146s may be performed by various etching processes such as wet etching and dry etching. In some embodiments, the process of etching the gate through structure sacrificial layer 146s may be performed using an etching material having a higher etch selectivity for the gate through structure sacrificial layer 146s compared to a material included in the sacrificial insulating layer 130s and a material included in the interlayer insulating layer 132.

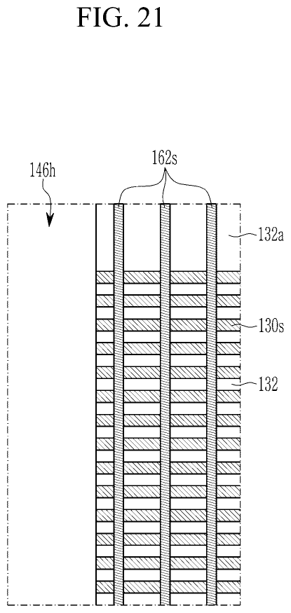

As illustrated in FIG. 21, a process of enlarging the first preliminary through hole 146h may be performed. A process of enlarging the first preliminary through hole 146h may be performed by, e.g., a wet etching process, but the embodiments are not limited thereto. As the process of enlarging the first preliminary through hole 146h is performed, a width of the first preliminary through hole 146h in the horizontal direction may increase.

In some embodiments, as the process of enlarging the first preliminary through hole 146h is performed, some of the first preliminary through holes 146h positioned in at least some regions may be merged. Specifically, as a process of expanding the first preliminary through holes 146h is performed, the first preliminary through holes 146h positioned in a region where the first separation pattern 164 is to be formed may be merged with each other. Accordingly, the first preliminary through holes 146h positioned in the region where the first separation pattern 164 is to be formed may have a line shape extending in the second direction Y.

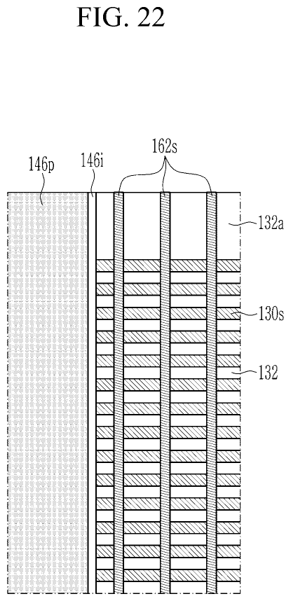

Next, as illustrated in FIG. 22, after an insulating liner 146i is conformally formed on a sidewall of the first preliminary through hole 146h, a preliminary gate through structure 146p that at least partially fills the others of the first preliminary through holes 146h may be formed on the insulating liner 146i. In some embodiments, the insulating liner 146i may include an insulating material. For example, the insulating liner 146i may include at least one of a silicon oxide, a silicon nitride, or a silicon oxynitride. In some embodiments, the insulating liner 146i may include a sacrificial insulation layer 130s and a material having etch selectivity. The preliminary gate through structure 146p may include at least one of polycrystalline silicon, tungsten, titanium nitride, or carbon. However, the embodiments are not limited thereto, and the preliminary gate through structure 146p may include various materials.

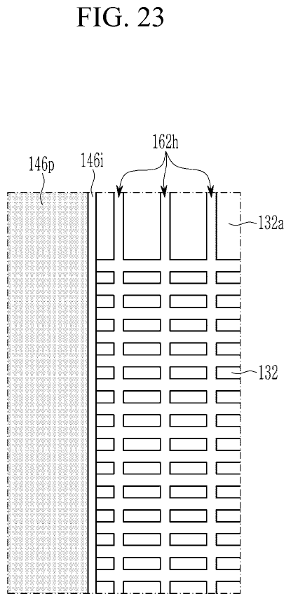

As illustrated in FIGS. 23 and 24, a second preliminary through hole 162h may be formed by removing portions of the support structure sacrificial layer 162s and the sacrificial insulating layer 130s. First, the support structure sacrificial layer 162s positioned at a portion where the support structure 162 is to be formed and a portion where the second separation pattern 166 is to be formed may be removed by an etching process. A process of etching the support structure sacrificial layer 162s may be performed by various etching processes such as wet etching and dry etching.

Next, a portion of the sacrificial insulating layer 130s may be etched through a surface of the sacrificial insulating layer 130s exposed through or by the second preliminary through hole 162h. In this case, a process of etching some regions of the sacrificial insulating layer 130s may be performed using an etching material having a higher etch selectivity for the sacrificial insulating layer 130s compared to the interlayer insulating layer 132. As the sacrificial insulating layer 130s is selectively etched in the sacrificial insulating layers 130s and interlayer insulating layers 132 alternately stacked, a width of the second preliminary through hole 162h may be expanded in the horizontal direction in a region that overlaps the sacrificial insulating layer 130s that remains unetched within the stack structure 120s in the horizontal direction.

Accordingly, referring to FIGS. 23 and 24, at least some of the second preliminary through holes 162h may be merged in a region that horizontally overlaps at least a portion of the sacrificial insulating layer 130s that remains unetched within the stacked structure 120s. In some embodiments, some regions of the second preliminary through holes 162h positioned in a region where the second separation pattern 166 is to be formed may be merged. Accordingly, the second preliminary through hole 162h positioned in a region where the second separation pattern 166 is to be formed may have a line shape extending in the second direction Y or in the diagonal direction between the first direction X and the second direction Y in the region that horizontally overlaps at least a portion of the sacrificial insulating layer 130s that remains unetched within the stack structure 120s.

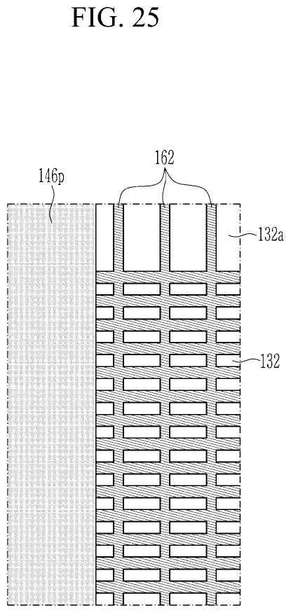

As illustrated in FIGS. 25 and 26, the second preliminary through hole 162h may be at least partially filled with an insulating material to form the support structure 162 and the second separation pattern 166. In some embodiments, the process of filling the second preliminary through hole 162h with an insulating material may be performed by atomic layer deposition (ALD). However, the embodiments are not limited thereto, and the process of filling the second preliminary through hole 162h with an insulating material may be performed by various deposition processes.

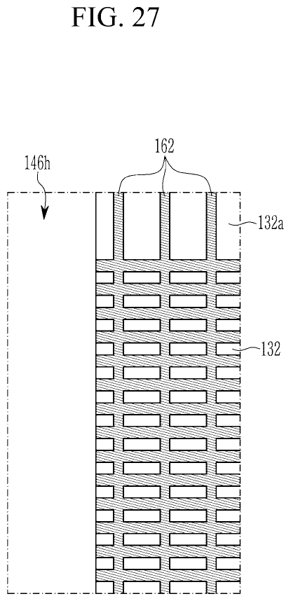

As illustrated in FIGS. 27 and 28, the preliminary gate through structure 146p and the insulating liner 146i that filled the first preliminary through hole 146h may be removed again by an etching process.

Thereafter, as shown in FIGS. 29 to 31, the sacrificial insulating layer 130s may be etched through the surface of the sacrificial insulating layer 130s exposed through or by the first preliminary through hole 146h (see FIGS. 27 and 28). In this case, a process of etching the sacrificial insulating layer 130s may be performed using an etching material having a higher etch selectivity for the sacrificial insulating layer 130s compared etching the interlayer insulating layer 132. Thereafter, a conductive material may be buried in a portion where the sacrificial insulating layer 130s has been removed to form the gate electrode 130. After forming the gate electrode 130, the first preliminary through hole 146h may be at least partially filled with an insulating material to form the gate through structure 146 and the first separation pattern 164. Specifically, an insulating material may be at least partially filled in the first preliminary through hole 146h illustrated in FIG. 28 to form the gate through structure 146, and the first preliminary through-hole 146h illustrated in FIG. 27 may be at least partially filled to form the first separation pattern 164.

Next, as illustrated in FIGS. 32 and 33, the through sacrificial layer (reference numeral 190s of FIG. 18) may be removed, and a lower portion of the sidewall insulating layer 190i (i.e., a portion overlapping the through sacrificial layer 190s in the third direction Z) may be removed. Then, the through hole PH may be at least partially filled with a conductive material to form the conductive portion 190m. In this way, the gate contact portion 190 may be formed.

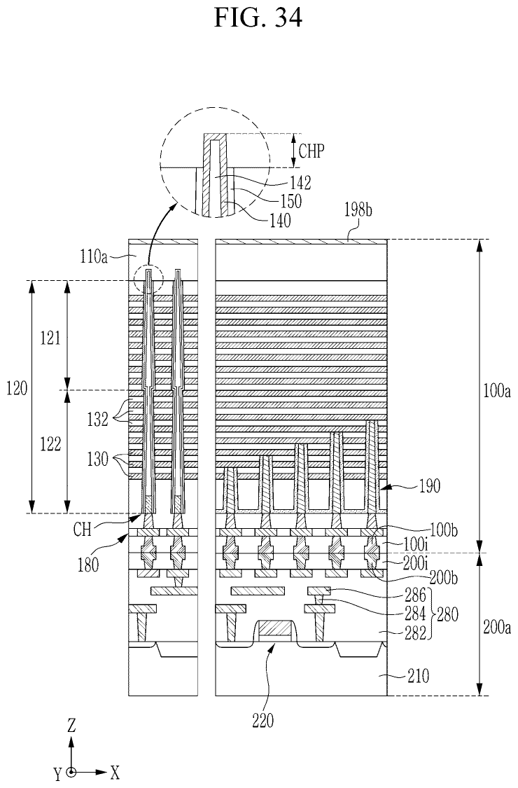

FIG. 34 illustrates a partial cross-sectional view schematically showing a semiconductor device according to some embodiments.

Referring to FIG. 34, the semiconductor device according to the embodiment may have a chip to chip (C2C) structure bonded by a wafer bonding method. That is, a lower chip including a circuit region 200a in which a peripheral circuit structure is provided on the first substrate 210 may be manufactured, an upper chip including a cell region 100a in which a memory cell structure is provided on a preliminary substrate may be manufactured, and then these may be bonded to manufacture the semiconductor device.

The circuit region 200a may include a first substrate 210, a circuit element 220, a first wiring portion 280, and a first bonding structure 200b electrically connected to the first wiring portion 280 and positioned on a surface facing the cell region 100a. On the surface facing the cell region 100a, a region other than the first bonding structure 200b may be covered or at least partially overlapped by a first bonding insulating layer 200i.

The cell region 100a may include a second substrate 110a, a gate stack structure 120, a channel structure CH, a second wiring portion 180, and a second bonding structure 100b electrically connected to the second wiring portion 180 and positioned on a surface facing the circuit region 200a. A region other than the second bonding structure 100b may be covered or at least partially overlapped by the second bonding insulating layer 100i.

In some embodiments, the second substrate 110a may be a semiconductor layer including a semiconductor material. For example, the second substrate 110a may be formed of a semiconductor layer including monocrystalline or polycrystalline silicon, germanium, silicon-germanium, etc. In some embodiments, the second substrate 110a may further include an insulating layer. For example, after bonding the cell region 100a to the circuit region 200a, the preliminary substrate provided in the cell region 100a may be removed, and a semiconductor layer and/or an insulating layer may be formed.

In some embodiments, the gate stack structure 120 may be sequentially stacked on a lower portion of the second substrate 110a, thereby having a structure in which the gate stack structure 120 illustrated in FIG. 3 is inverted or flipped upside down. Then, the channel structure CH extending through or into the gate stack structure 120 may also have a structure that is the channel structure CH shown in FIG. 4 inverted or flipped upside down. Accordingly, the channel structure CH may have an inclined or sloped side surface such that a width thereof becomes narrower from the circuit region 200a toward the second substrate 110a when viewed in cross section. Then, the channel pad 144 and the second wire portion 180 positioned on the gate stack structure 120 may be positioned adjacent to the circuit region 200a.

For example, the first bonding structure 200b and/or the second bonding structure 100b may be made of aluminum, copper, tungsten, or an alloy thereof. For example, the first and second bonding structures 200b and 100b include copper, so the cell region 100a and the circuit region 200a may be bonded by copper-to-copper bonding (directly contacted and bonded).

In some embodiments, the channel structure CH may include a protrusion CHP protruding or extending from a surface opposite to the second wiring portion 180 in the gate stack structure 120. The protrusion CHP is not provided with a gate dielectric layer 150, so the gate stack structure 120 of the channel layer 140 positioned in the protrusion CHP may be exposed to the outside. The second substrate 110a may be electrically connected to the channel layer 140 positioned at the protrusion CHP. However, the embodiments are not limited thereto and may include horizontal conductive layers 112 and 114 as illustrated in FIG. 3. Numerous other variations are possible.

A semiconductor device according to an example may include input/output pads and an input/output connection wire electrically connected thereto. The input/output connecting wire may be electrically connected to a portion of the second bonding structure 100b. The input/output pad may be positioned on, for example, an insulating layer 198b covering or at least partially overlapping an outer surface of the second substrate 110a. According to some embodiments, a separate input/output pad electrically connected to the circuit region 200a may be provided.

For example, the circuit region 200a and the cell region 100a may respectively be portions corresponding to a first structure 1100F and a second structure 1100S of a semiconductor device 1100 included in an electronic system 1000 illustrated in FIG. 35. In some embodiments, the circuit region 200a and the cell region 100a may be regions including a first structure 4100 and a second structure 4200 of a semiconductor chip 2200a illustrated in FIG. 36, respectively.

An example of an electronic system including the aforementioned semiconductor device will be described in detail.

FIG. 35 schematically illustrates an electronic system including a semiconductor device according to some embodiments.

Referring to FIG. 35, the electronic system 1000 according to some embodiments may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive (SSD) device including one or the plurality of semiconductor devices 1100, a universal serial bus (USB), a computing system, a medical device, or a communication apparatus.

The semiconductor device 1100 may be a non-volatile memory device, and may be, for example, a NAND flash memory device described with reference to FIG. 1 to FIG. 33. The semiconductor device 1100 may include a first structure 1100F and a second structure 1100S on the first structure 1100F. In some embodiments, the first structure 1100F may be positioned next to the second structure 1100S. The first structure 1100F may be a peripheral circuit structure including a decoder circuit 1110, a page buffer 1120, and a logic circuit 1130. The second structure 1100S may be a memory cell structure including a bitline BL, a common source line CSL, a word line WL, first and second gate upper lines UL1 and UL2, and first and second gate lower lines LL1 and LL2, and a memory cell string CSTR between the bitline BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT positioned between the lower transistors LT1 and LT2 and the upper transistors UT1 and UT2. A number of lower transistors LT1 and LT2 and a number of upper transistors UT1 and UT2 may be variously modified in some embodiments.

In some embodiments, the lower transistors LT1 and LT2 may include ground selective transistors, and the upper transistors UT1 and UT2 may include string selective transistors. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connecting wire 1115 extending from the first structure 1100F to the second structure 1100S. The bitline BL may be electrically connected to the page buffer 1120 through a second connecting wire 1125 extending to the second structure 1100S in the first structure 1100F.

In the first structure 1100F, the decoder circuit 1110 and the page buffer 1120 may execute a control operation on at least one memory cell transistor selected from among the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connecting wire 1135 extending from the first structure 1100F to the second structure 1100S.

The controller 1200 may include a processor 1210, a NAND controller 1220, and a host interface 1230. According to some embodiments, the electronic system 1000 may include a plurality of semiconductor devices 1100, and in this case, the controller 1200 may control the semiconductor devices 1100.

The processor 1210 may control an overall operation of the electron system 1000 including the controller 1200. The processor 1210 may operate according to predetermined firmware, and may access the semiconductor devices 1100 by controlling the NAND controller 1220. The NAND controller 1220 may include a NAND interface 1221 that processes communication with the semiconductor devices 1100. A control command for controlling the semiconductor device 1100, data to be recorded in the memory cell transistor MCT of the semiconductor device 1100, and data to be read from the memory cell transistor MCT of the semiconductor device 1100 may be transmitted through the NAND interface 1221. The host interface 1230 may provide a communication function between the electronic system 1000 and an external host. When a control command is received from an external host through the host interface 1230, the processor 1210 may control the semiconductor devices 1100 in response to the control command.

FIG. 36 illustrates a schematic perspective view showing an electronic system including a semiconductor device according to some embodiments.

Referring to FIG. 36, an electronic system 2000 according to some embodiments may include a main substrate 2001, a controller 2002 mounted on the main substrate 2001, one or more semiconductor packages 2003, and a DRAM 2004. The semiconductor package 2003 and the DRAM 2004 may be connected to the controller 2002 through a wiring pattern 2005 positioned on the main substrate 2001.

The main substrate 2001 may include a connector 2006 including a plurality of pins coupled to an external host. A number and disposition of the pins in the connector 2006 may vary depending on a communication interface between the electronic system 2000 and the external host. In some embodiments, the electronic system 2000 may communicate with the external host according to any one of interfaces such as a universal flash storage (USB), a peripheral component interconnect express (PCI-Express), a serial advanced technology attachment (SATA), M-Phy for universal flash storage (UFS), and the like. In some embodiments, the electronic system 2000 may operate with power supplied from an external host through the connector 2006. The electronic system 2000 may further include a power management integrated circuit (PMIC) that distributes power supplied from the external host to the controller 2002 and semiconductor package 2003.

The controller 2002 may record data in the semiconductor package 2003, or may read data from the semiconductor package 2003, and may improve an operation speed of the electronic system 2000.

The DRAM 2004 may be a buffer memory for buffering a speed difference between the semiconductor package 2003, which is a data storage space, and an external host. The DRAM 2004 included in the electronic system 2000 may also operate as a kind of cache memory, and may provide a space for temporarily storing data in the control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, a semiconductor chip 2200 on the package substrate 2100, an adhesive layer 2300 disposed on a lower surface of each semiconductor chip 2200, a connecting structure 2400 that electrically connects the semiconductor chip 2200 and the package substrate 2100, and a molding layer 2500 covering or overlapping the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 35. Each semiconductor chip 2200 may include a gate stack structure 3210 and a channel structure 3220. The semiconductor chip 2200 may include the semiconductor device described with reference to FIG. 1 to FIG. 33.

In some embodiments, the connecting structure 2400 may be a bonding wire electrically connecting the input/output pad 2210 and the package upper pad 2130. Accordingly, the semiconductor chips 2200 may be electrically connected to each other by using a bonded wire method, and may be electrically connected to the package upper pad 2130 of the package substrate 2100 in each of the first and second semiconductor packages 2003a and 2003b. According to some embodiments, the semiconductor chips 2200 may be electrically connected to each other by a connecting structure including a through silicon via (TSV) instead of the bonding wire connecting structure 2400 in each of the first and second semiconductor packages 2003a and 2003b.

In some embodiments, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wire positioned on the interposer substrate.

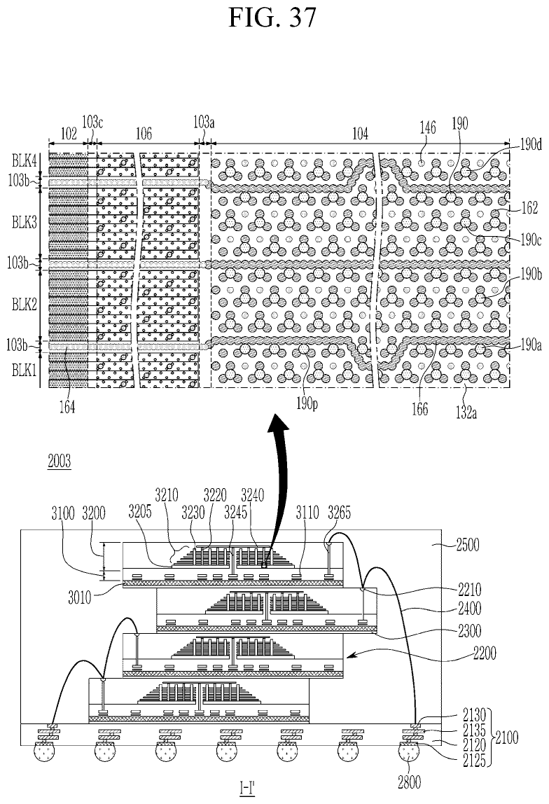

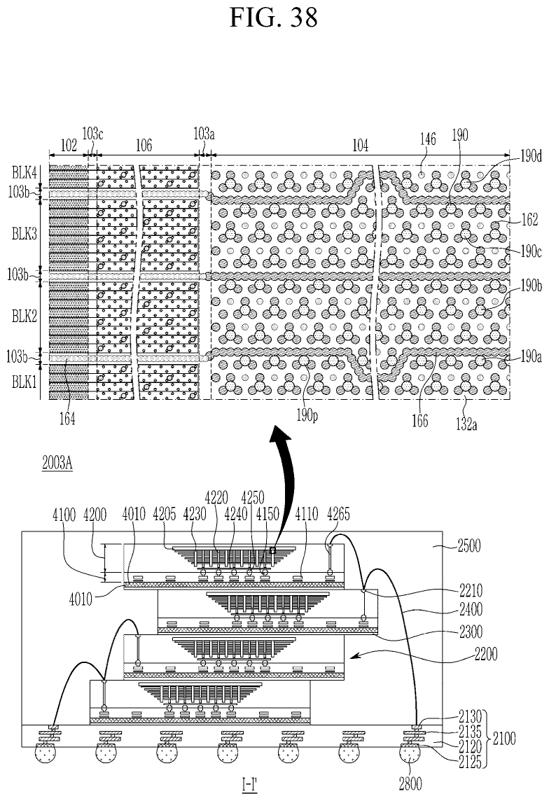

FIG. 37 and FIG. 38 each illustrate a schematic cross-sectional view showing a semiconductor package according to some embodiments. FIG. 37 and FIG. 38 each illustrate some embodiments of the semiconductor package 2003 of FIG. 35, and conceptually illustrates a region of the semiconductor package 2003 of FIG. 36 taken along a line I-I′.

Referring to FIG. 37, in the semiconductor package 2003, the package substrate 2100 may be a printed circuit board. The package substrate 2100 may include a package substrate body 2120, a package upper pad 2130 positioned on an upper surface of the package substrate body 2120, a package lower pad 2125 positioned on or exposed through or by the lower surface of the package substrate body 2120, and an inner wire 2135 that electrically connects the package upper pad 2130 and the package lower pad 2125 inside the package substrate body 2120. The package upper pad 2130 may be electrically connected to the connecting structure 2400. The package lower pad 2125 may be connected to the wire pattern 2005 of the main substrate 2001 of the electronic system 2000 through a conductive connector 2800 as illustrated in FIG. 35.

The semiconductor chip 2200 may each include a semiconductor substrate 3010, and a first structure 3100 and a second structure 3200 stacked in turn on the semiconductor substrate 3010. The first structure 3100 may include a peripheral circuit region including a peripheral wire 3110. The second structure 3200 may include a common source line 3205, a gate stack structure 3210 on the common source line 3205, a channel structure 3220 and a separating structure 3230 extending into or through the gate stack structure 3210, a bitline 3240 electrically connected to the channel structure 3220, and a gate connecting wire electrically connected to a word line (reference sign WL of FIG. 35) of the gate stack structure 3210.

In the semiconductor chip 2200 or a semiconductor device according to some embodiments, gate contact portions 190 may be arranged with improved efficiency without wasting space in the entire connection region 104, and accordingly, a width of the entire connection region 104 along the second direction Y may be reduced, and a size of the semiconductor chip 2200 or the semiconductor device may be reduced.

Each of the semiconductor chips 2200 may include a through wire 3245 that is electrically connected to the peripheral wire 3110 of the first structure 3100 and extends into the second structure 3200. The through wire 3245 may extend through or into the gate stack structure 3210, and may be further positioned outside the gate stack structure 3210. Each semiconductor chip 2200 may further include an input/output connection wire 3265 electrically connected to the peripheral wire 3110 of the first structure 3100 and an input/output pad 2210 electrically connected to the input/output connecting wire 3265 extending into the second structure 3200.

In some embodiments, a plurality of semiconductor chips 2200 in the semiconductor package 2003 may be electrically connected to each other by a connecting structure 2400 having a form of a bonding wire. As another example, the semiconductor chips 2200 or a plurality of portions constituting the semiconductor chips 2200 may be electrically connected by a connecting structure including the through silicon via (TSV).

Referring to FIG. 38, in a semiconductor package 2003A, each semiconductor chip 2200a may include a semiconductor substrate 4010, a first structure 4100 on the semiconductor substrate 4010, and a second structure 4200 bonded to a first structure 4100 by wafer bonding on the first structure 4100.

The first structure 4100 may include a peripheral circuit region including a peripheral wire 4110 and a first junction structure 4150. The second structure 4200 may include a common source line 4205, a gate stack structure 4210 between the common source line 4205 and the first structure 4100, a channel structure 4220 and a separating structure 4230 extending through or into the gate stack structure 4210, and a second junction structure 4250 electrically connected to the word line (reference numeral WL in FIG. 35, hereinafter the same) of each of the channel structure 4220 and the gate stack structure 4210. For example, the second junction structure 4250 may be electrically connected to the channel structure 4220 and the word line WL extending into or through a bit line 4240 electrically connected to the channel structure 4220 and a gate connecting wire electrically connected to the word line WL, respectively. The first junction structure 4150 of the first structure 4100 and the second junction structure 4250 of the second structure 4200 may be bonded while contacting each other. A bonded portion of the first junction structure 4150 and the second junction structure 4250 may be formed of, e.g., copper (Cu).

In the semiconductor chip 2200 or a semiconductor device according to some embodiments, gate contact portions 190 may be arranged with improved efficiency without wasting space in the entire connection region 104, and accordingly, a width of the entire connection region 104 along the second direction Y may be reduced, and a size of the semiconductor chip 2200 or the semiconductor device may be reduced.

Each of the semiconductor chips 2200a may further include an input/output pad 2210 and an input/output connecting wire 4265 under the input/output pad 2210. The input/output connecting wire 4265 may be electrically connected to a portion of the second junction structure 4250.

In some embodiments, a plurality of semiconductor chips 2200a in the semiconductor package 2003A may be electrically connected to each other by a connecting structure 2400 having a form of a bonding wire. As another example, the semiconductor chips 2200a or a plurality of portions of the semiconductor chips 2200 may be electrically connected by a connecting structure including the through silicon via (TSV).

Although the embodiments have been described in detail above, the scope of the present disclosure is not limited thereto. Various modifications and improvements made by those skilled in the art using the basic concept of the present disclosure as defined in the following claims may also fall within the scope of the present disclosure.

What is claimed is:

1. A semiconductor device comprising:
a substrate that comprises a cell array region and a connection region;
first gate stack structures and second gate stack structures that are spaced apart from each other in a first direction and are on the cell array region and the connection region, wherein each of the first gate stack structures and the second gate stack structures comprises interlayer insulating layers and gate electrodes that are alternately stacked;
channel structures that extend into a first set of the first gate stack structures and a first set of the second gate stack structures that are on the cell array region;
first gate contact portions that extend into a second set of the first gate stack structures that are on the connection region;
second gate contact portions that extend into a second set of the second gate stack structures that are on the connection region;
a first separation pattern that is between the first set of first gate stack structures and the first set of second gate stack structures and extends in a second direction intersecting the first direction; and
a second separation pattern that is between the second set of first gate stack structures and the second set of second gate stack structures, wherein a first end of the second separation pattern contacts the first separation pattern, and wherein the second separation pattern extends diagonally between the first direction and the second direction.

2. The semiconductor device of claim 1, further comprising:
support structures that extend into the second set of the first gate stack structures and the second set of the second gate stack structures and extend around the first gate contact portions and the second gate contact portions,
wherein a width in the first direction of a region comprising a portion of the support structure and a portion of the second separation pattern that at least partially overlap a first gate electrode of the gate electrodes in the first direction is different from a width of a region that at least partially overlaps a first interlayer insulating layer of the interlayer insulating layers in the first direction.

3. The semiconductor device of claim 2, wherein the support structures and the second separation pattern comprise a same material.

4. The semiconductor device of claim 1, further comprising:
gate through structures that extend into the first set of the first gate stack structures and the first set of the second gate stack structures on the connection region,
wherein a width in the first direction of a first gate through structure of the gate through structures and a width in the first direction of the first separation pattern are equal.

5. The semiconductor device of claim 4, wherein the gate through structures and the first separation pattern comprise a same material.

6. The semiconductor device of claim 4, wherein the gate through structures are spaced apart from the first gate contact portions and the second gate contact portions in at least one of the first direction or the second direction.

7. The semiconductor device of claim 1, wherein at least one of the first gate contact portions or the second gate contact portions at least partially overlaps the first separation pattern in the second direction.

8. The semiconductor device of claim 1, wherein:
the first gate contact portions and the second gate contact portions are spaced apart from each other in the first direction and the second direction, and
a number of first rows of the first gate contact portions that extends in the first direction and a number of second rows of the second gate contact portions that extends in the second direction are different.

9. The semiconductor device of claim 8, wherein the first gate contact portions or the second gate contact portions have a hexagonal shape, a zigzag shape, or a matrix shape in a plan view.

10. The semiconductor device of claim 1, wherein a first end of the first separation pattern and the first end of the second separation pattern contact each other on a boundary region between the cell array region and the connection region.

11. The semiconductor device of claim 10, wherein the second separation pattern extends diagonally between the first direction and the second direction on the boundary region.

12. The semiconductor device of claim 1, wherein:
the first gate contact portions, the second gate contact portions, and the first separation pattern extend into the first gate stack structures in a third direction intersecting the first direction and the second direction, and
a width in the first direction of a first one of the first gate contact portions, a width in the first direction of a first one of the second gate contact portions, and a width in the first direction of the first separation pattern are equal.

13. The semiconductor device of claim 12, further comprising sidewall insulating layers that extend around the first separation pattern, side surfaces of the first gate contact portions, and side surfaces of the second gate contact portions.

14. The semiconductor device of claim 1, wherein, in the first direction or the second direction, a distance between a first one of the first gate contact portions that is adjacent to the second separation pattern and a second of the first gate contact portions that is adjacent to the first one of the first gate contact portions is equal to a distance between the first one of the first gate contact portions and a first one of the second gate contact portions that is adjacent to the first one of the first gate contact portions.

15. The semiconductor device of claim 1, wherein a number of the first gate contact portions and a number of the second gate contact portions are equal.

16. A semiconductor device comprising:
a substrate that comprises a cell array region and a connection region;
first gate stack structures and second gate stack structures that are spaced apart from each other in a first direction and are on the cell array region and the connection region, wherein each of the first gate stack structures and the second gate stack structures comprises interlayer insulating layers and gate electrodes that are alternately stacked;
channel structures that extend into a first set of the first gate stack structures and a first set of the second gate stack structures in the cell array region;
first gate contact portions that extend into a second set of the first gate stack structures that are on the connection region;
second gate contact portions that extend into a second set of the second gate stack structures that are on the connection region;
a first separation pattern that is between the first set of first gate stack structures and the first set of second gate stack structures and extends in a second direction intersecting the first direction; and
second separation pattern that is between the second set of first gate stack structures and the second set of second gate stack structures and comprises a first end that contacts the second separation pattern,
wherein a width in the first direction of a portion of the second separation pattern that at least partially overlaps the gate electrode in the first direction is different from a width of a region that at least partially overlaps the interlayer insulating layer in the first direction.

17. The semiconductor device of claim 16, wherein the second separation pattern comprises a portion that extends diagonally between the first direction and the second direction.

18. The semiconductor device of claim 16, further comprising support structures that are on the connection region and extend into the second set of the first gate stack structures and the second set of the second gate stack structures,
wherein a width in the first direction of a portion of the support structure that at least partially overlaps a first gate electrode of the gate electrodes in the first direction is different from the width of the region that at least partially overlaps a first interlayer insulating layer of the interlayer insulating layers in the first direction.

19. The semiconductor device of claim 16, further comprising gate through structures that extend into the first set of the first gate stack structures and the first set of the second gate stack structures on the connection region,
wherein a width in the first direction of a first gate through structure of the gate through structures and a width in the first direction of the first separation pattern are equal.

20. An electronic system comprising:
a main substrate;
a semiconductor device on the main substrate; and
a controller electrically connected to the semiconductor device on the main substrate,
wherein the semiconductor device comprises:
a substrate that comprises a cell array region and a connection region;
first gate stack structures and second gate stack structures that are spaced apart from each other in a first direction and are on the cell array region and the connection region, wherein each of the first gate stack structures and the second gate stack structures comprises interlayer insulating layers and gate electrodes that are alternately stacked;
channel structures that extend into a first set of the first gate stack structures and a first set of the second gate stack structures that are on the cell array region;
first gate contact portions that extend into a second set of the first gate stack structures that are on the connection region;
second gate contact portions that extend into a second set of the second gate stack structures that are on the connection region;
a first separation pattern that is between the first set of first gate stack structures and the first set of second gate stack structures and extends in a second direction intersecting the first direction; and
a second separation pattern that is between the second set of first gate stack structures and the second set of second gate stack structures, wherein a first end of the second separation pattern contacts the first separation pattern, and wherein the second separation pattern extends diagonally between the first direction and the second direction.
